(19) United States
(12) Patent Application Publication
(10) Pub. No.: US 2023/0093111 A1
(43) Pub. Date: Mar. 23, 2023

(54) MULTI-FINGER RF nFET HAVING BURIED STRESSOR LAYER AND ISOLATION TRENCHES BETWEEN GATES

(71) Applicant: Acorn Semi, LLC, Palo Alto, CA (US)

(72) Inventor: Paul A. Clifton, Redwood City, CA (US)

(21) Appl. No.: 17/934,036

(22) Filed: Sep. 21, 2022

Related U.S. Application Data
(60) Provisional application No. 63/261,490, filed on Sep. 22, 2021.

(51) Int. Cl. H01L 27/12; H01L 23/66; H01L 29/40; H01L 29/417; H01L 29/06; H01L 29/78; H01L 21/8238; H01L 21/762

(52) U.S. Cl. CPC H01L 27/1207; H01L 23/66; H01L 27/1203; H01L 29/401; H01L 29/41775; H01L 29/0696; H01L 29/7845; H01L 21/823871; H01L 21/823878; H01L 21/76283; H01L 21/76267; H01L 2223/6605

(57) ABSTRACT

An RF MOSFET includes respective pluralities of gate fingers, source fingers, and drain fingers formed on a semiconductor structure. The gate fingers are spaced apart from each other along a first direction, extend in a second, orthogonal direction, and are electrically connected to one another through a gate mandrel. The source fingers are spaced apart from each other along the first direction, extend in the second direction, and are electrically connected to one another through a source mandrel. The drain fingers are spaced apart from each other along the first direction, extend in the second direction, and are electrically connected to one another through a drain mandrel. Adjacent unit cell transistors of the RF MOSFET are separated from one another by a dummy gate and a trench that extends into the semiconductor structure. The semiconductor structure may be a bulk semiconductor wafer, a PD-SOI wafer, or an FD-SOI wafer.

### RELATED APPLICATIONS

This is a NONPROVISIONAL of, claims priority to, and incorporates by reference U.S. Provisional Application 63/261,490, filed 22 Sep. 2021.

### FIELD OF THE INVENTION

The present invention relates to strained semiconductor MOSFET devices, and in particular embodiments to multi-finger radio frequency (RF) MOSFET devices, including strained fully-depleted and partially-depleted RF MOSFETs, formed using substrates having a buried stressor layer to provide said devices with strained silicon active regions and to methods of making such devices.

### BACKGROUND

Strained silicon is widely viewed as an important technology for obtaining desired advancements in integrated circuit performance. Mobility enhancement results from a combination of reduced effective carrier mass and reduced intervalley (phonon) scattering. N-channel metal oxide semiconductor field effect transistors (MOSFET), for example, achieve improved performance with induced uniaxial tensile strain in the channel region directed along the length axis of the MOSFET between the source and drain.

Strained silicon is conventionally obtained by first growing a thick layer of silicon germanium alloy (SiGe) on a silicon substrate. The SiGe layer is grown to a sufficient thickness that the SiGe layer is relaxed to an unstrained condition at its surface. The in-plane lattice parameter of the SiGe surface is similar to that of a bulk crystal of SiGe of the same composition. SiGe alloys have larger lattice parameters than silicon. Hence the relaxed surface of the SiGe layer provides an in-plane lattice parameter larger than that of silicon. A subsequent thin layer of silicon is grown epitaxially on the relaxed surface of the SiGe layer. The thin epitaxial layer of silicon assumes the larger in-plane lattice parameter of the SiGe and grows in a strained state with bonds in the crystal lattice elongated in the growth plane. This approach, sometimes known as substrate-strained silicon or “virtual substrate” technology, grows a thin pseudomorphic layer of strained silicon on the relaxed surface of a SiGe layer.

So long as the strained silicon layer does not exceed a “critical thickness” for strain relaxation and some care is taken, the tensile strain is maintained in the strained silicon layer through the various implantation and thermal processing steps typical of complementary metal oxide semiconductor (CMOS) manufacturing.

The use of relaxed SiGe as a “virtual substrate” to strain a subsequently deposited epitaxial silicon layer inevitably requires acceptance of a very high dislocation density in the SiGe layer because the SiGe relaxation mechanism is plastic in nature. In other words, relaxation in the SiGe layer occurs through the generation of strain-relieving misfit dislocations. A thin SiGe layer of suitable germanium concentration may be grown epitaxially on a silicon substrate without strain relaxation and exhibits few misfit dislocations if the SiGe layer is not thicker than a “critical thickness” at which misfit dislocations are generated. On the other hand, if the SiGe layer is thicker than the “critical thickness,” the strained SiGe lattice undergoes plastic deformation and most or all of the misfit strain is relieved by the nucleation and propagation of misfit dislocations. Some fraction of the resulting misfit dislocations gives rise to threading dislocations (at least 10⁴-10⁵ cm⁻²) which propagate through the overlying strained silicon layer. Threading dislocations represent extended defects and give rise to multiple undesirable consequences in MOSFETs including source/drain junction leakage, reduction of channel mobility, variability of threshold voltage and enhanced diffusion paths for dopants, leading to potential drain-to-source shorting in short-channel MOSFETs.

Semiconductor on insulator (SOI) wafers afford certain advantages over conventional bulk silicon wafers. An SOI wafer may, for example, have a layer of silicon on top of a layer of insulator. SOI with a buried oxide (typically abbreviated to “BOX”) layer between the top (active) silicon structure and an underlying crystalline silicon host or ‘handle’ wafer is the preferred SOI configuration for CMOS applications. An SOI wafer with a BOX layer structure may be formed by a combination of high dose implantation of oxygen and annealing (accomplished, for example, using the so-called SIMOX process). An SOI wafer may also be formed by wafer bonding a layer of silicon with a BOX layer on its surface from a donor wafer onto a handle wafer and subsequently separating the bulk of the donor wafer leaving behind the desired bonded thin silicon layer on top of the BOX on the handle wafer. Separation of the bulk of the donor wafer may be facilitated by subjecting the donor wafer to hydrogen ion implantation prior to bonding to create a defect layer at a depth corresponding to the desired thickness of the thin silicon layer. By subsequently applying a force to laterally section the bonded wafer structure along the plane of the damage layer, a silicon on insulator wafer may be separated from the donor wafer. An example of a process that forms BOX layers by this method is described in U.S. Pat. No. 6,372,609, and such wafers are commercially available from Soitec, Inc., of Bernin, France. The BOX layers of conventional SOI wafers are not compressively stressed.

If the silicon layer on top of the BOX layer is thicker than approximately 50 nm, the silicon layer will not be fully depleted in normal operation of CMOS transistors. Such wafers are known as partially-depleted SOI (PD-SOI). If the silicon layer on top of the BOX layer is thinner than approximately 50 nm, the silicon layer may be fully depleted in normal operation of CMOS transistors and such wafers are known as fully-depleted SOI (FD-SOI, also known as ultra-thin body SOI or UBSOI or ultra-thin body and BOX SOI, UTBB-SOI). Ultra-thin body, fully depleted MOSFETs fabricated in ultra-thin SOI have multiple beneficial features which each contribute to improved transistor and integrated circuit performance including low sensitivity to semiconductor body doping, low source and drain junction capacitances, improved electrical isolation between neighboring MOSFETs and improved control of short channel effects and the ability to utilize back bias through an n-type or p-type doped well under the BOX that is operated as a back gate.

An FDSOI technology in which the semiconductor active regions have in-plane tensile strain could have the combined benefits of ultra-thin body semiconductor-on-insulator and of strained silicon. Various approaches to obtaining “strained silicon on insulator” have been described. U.S. Pat. No. 7,534,701 to Ghyselen, et al. describes a strained silicon-on-insulator manufacturing method wherein a blanket strained silicon layer is first formed on a relaxed surface of single crystal silicon germanium and subsequently bonded to a handle wafer with an oxide layer such that the strained silicon layer is transferred to the handle wafer. The tensile strain is retained in the thin strained silicon layer after separation of the silicon germanium, for example, by the SmartCut process described in the above-cited U.S. Pat. No. 6,372,609.

U.S. Pat. No. 6,372,609 to Wristers, et. al., describes forming an SOI wafer with a buried, compressively stressed silicon nitride layer in an ineffective attempt to create tensile strain in the thin top (surface) silicon layer. The Wristers patent does not in fact induce effective strain in the top semiconductor layer. The process described in the Wristers patent, forms a BOX structure including a layer of compressively stressed silicon nitride and the final device structure includes the BOX structure positioned between an active region and a substrate. However, the compressively stressed silicon nitride layer is continuous (uninterrupted) in the plane of the wafer and so cannot expand or contract laterally from the as-formed configuration. There is no opportunity for edge relaxation of the buried stressed silicon nitride layer and as such the Wristers patent provides no mechanism for inducing strain in the silicon active region or for relaxing the compressively stressed buried silicon nitride layer.

U.S. Patent Publication No. 2009/0278201 of Chatty, et al., describes strained channel MOSFET devices on SOI wafers. The starting point is a wafer with a BOX layer on a substrate, with a silicon nitride layer above that and a surface active silicon layer in which MOSFETs will be constructed. This silicon nitride layer may be deposited in a state of compressive or tensile stress up to a maximum magnitude of 200 MPa. From this starting point, isolation trenches are cut through the active silicon layer and the silicon nitride layer underneath it, but stop at the BOX. Then some of the source and drain silicon in the active layer is removed and replaced with a compressive or tensile stressed material (e.g. silicon germanium or silicon:carbon respectively) so as to induce longitudinal compressive or tensile strain in the channel region of the MOSFET. Instead of obtaining significant strain in the channel region from edge relaxation and expansion of the silicon nitride layer, in the Chatty publication, the primary method of inducing strain in the channel region is the well known “embedded source/drain stressor” method. The Chatty publication focuses on using a buried silicon nitride layer as a stiffener against which the force of an embedded stressor in source/drain regions can react to create the desired strain in the channel region. The publication explains that if there is no source/drain embedded stressor present, measurements show that there is no difference in the stress in the channel either when (1) the silicon nitride stiffening layer is present or (2) the silicon nitride stressor is not present. It is clear, therefore, that the Chatty publication does not attempt to induce stress in the channel by the use of a buried silicon nitride stressor together with edge relaxation.

U.S. Pat. No. 7,338,834 to Clifton et al., assigned to the assignee of the present invention, describes a bulk wafer containing a compressively stressed buried stressor (BS) structure underlying a surface semiconductor layer. The compressively stressed buried stressor structure may be an epitaxial layer of silicon germanium alloy (abbreviated to SiGe). The surface semiconductor layer may be silicon. The surface semiconductor layer is etched such that trenches are cut through the surface semiconductor layer and the compressively stressed buried stressor structure into the base substrate, in a pattern defined by a mask layer. Etching the trenches allows the compressively stressed buried stressor structure to relax elastically, thereby causing the surface semiconductor layer to be tensile strained across a portion of its lateral extent between the trenches. The compressively stressed buried stressor layer is relaxed in-plane by elastic edge relaxation and a significant amount of in-plane tensile strain is induced in the semiconductor layer above, as well as in the upper part of the base substrate below. Thereafter, an integrated circuit device having an active region in the now tensile-strained surface semiconductor layer may be formed.

U.S. Pat. No. 8,395,213 to Clifton et al., assigned to the assignee of the present invention, describes an SOI wafer containing a compressively stressed buried insulator structure. In one example, the stressed buried insulator may be formed on a host wafer by forming silicon oxide, silicon nitride and silicon oxide layers so that the silicon nitride layer is compressively stressed. Wafer bonding provides the surface silicon layer over the stressed insulator layer. The surface semiconductor layer is etched such that trenches are cut through the surface semiconductor layer and the stressed buried insulator structure into the base substrate, in a pattern defined by a mask layer. Etching the trenches allows the stressed buried insulator structure to relax, thereby causing the surface semiconductor layer to be strained across a portion of its lateral extent between the trenches. Thereafter, an integrated circuit device having an active region in the now-strained surface semiconductor layer may be formed. A further embodiment described in U.S. Pat. No. 8,395,213 included depositing a buried stressor (BS) layer, e.g., a SiGe layer, on a first substrate that contains silicon, where the BS layer has a higher concentration of germanium than the first substrate so that the BS layer is in a state of in-plane compressive stress. A second substrate having an insulating layer (BOX) on one surface is then attached so that the insulating layer bonds to the BS layer. A portion of the second substrate is then removed, leaving a surface silicon layer on the insulating layer. Again, trenches are etched through the surface silicon layer, the insulating layer and the BS layer, and into the first substrate in a pattern defined by a mask layer, thereby straining the surface silicon layer across at least a portion of its width between walls of the trenches. An integrated circuit device may be formed with its active region in the surface silicon layer.

U.S. Pat. No. 10,672,646 to Schwarzenbach et al. describes a refinement of the invention described in U.S. Pat. No. 8,395,213 that includes an additional bonding layer (BL) on top of the BS layer. The BL typically comprises silicon and provides for an enhanced quality of the bonded interface between the BOX and the surface of the handle wafer.

U.S. Patent Publication No. US20210066463A1 of Utess et al. describes a layout optimization for radio frequency (RF) device performance and methods of manufacture. The structure includes an active device on a substrate; source and drain diffusion regions adjacent to the active device; and a first contact in electrical contact with the source and drain diffusion regions and which is spaced away from the first active device to optimize a stress component in a channel region of the first active device.

### SUMMARY OF THE INVENTION

Various embodiments of the invention are described below. Briefly, in one embodiment an RF MOSFET includes respective pluralities of gate fingers, source fingers, and drain fingers formed on a semiconductor structure. The gate fingers are spaced apart from each other along a first direction, extend in a second, orthogonal direction, and are electrically connected to one another through a gate mandrel that is electrically connected to a gate contact. The source fingers are spaced apart from each other along the first direction, extend in the second direction, and are electrically connected to one another through a source mandrel that is electrically connected to respective source contacts. The drain fingers are spaced apart from each other along the first direction, extend in the second direction, and are electrically connected to one another through a drain mandrel that is electrically connected to respective drain contacts. Further, the respective source, gate, and drain fingers are interdigitated so that each gate finger extends in the first direction between a pair of adjacent source and drain fingers. The RF MOSFET is electrically organized as a plurality of unit cell transistors electrically connected with one another and adjacent unit cell transistors of the RF MOSFET are separated from one another by a dummy gate and trench that extends into the semiconductor structure.

In some embodiments of the RF MOSFET, the semiconductor structure may be a bulk semiconductor substrate with a buried stressor layer disposed over the semiconductor substrate and a semiconductor layer disposed over the buried stressor layer. Alternatively, the semiconductor structure may be a PD-SOI wafer including a semiconductor substrate, a BOX layer disposed over the semiconductor substrate, a semiconductor layer disposed over the BOX layer, a buried stressor layer disposed over the semiconductor layer, and a partially depleted semiconductor layer disposed over the buried stressor layer. And in other instances the semiconductor structure may be an FD-SOI wafer that includes a semiconductor substrate, a buried stressor layer disposed over the semiconductor substrate, a BOX layer disposed over buried stressor layer, and a fully depleted semiconductor layer disposed over the BOX layer.

In any or all of the above-described embodiments, the dummy gates are not electrically connected to the gate mandrel; the gate, source and drain fingers may each be made of a conductive material, and each unit cell transistor may include one of the gate fingers, one of the source fingers, and one of the drain fingers, where the included source and drain fingers are on opposed sides of the included gate finger, and a portion of the semiconductor structure that underlies the included gate, source and drain fingers.

In any or all of the above-described embodiments, the source fingers and drain fingers may include elevated epitaxial silicon source/drain regions and a source/drain of each unit cell transistor may be located inside the included portion of the semiconductor structure that underlies an adjacent a channel region below a respective included gate finger. Further, in any or all of the above-described embodiments, the buried stressor layer may be or may include SiGe.

In various ones of the embodiments of the RF MOSFET, the trenches may extend through the semiconductor layer and the buried stressor layer and into the underlying substrate. Alternatively, the trenches may extend through the partially depleted semiconductor layer, the buried stressor layer, the semiconductor layer, and into the BOX layer. Or, the trenches may extend through the partially depleted semiconductor layer, the buried stressor layer, the semiconductor layer, the BOX layer and partially into the substrate. Or, the trenches may extend through the fully depleted semiconductor layer, the BOX layer, the buried stressor layer, and into the substrate.

### BRIEF DESCRIPTION OF THE DRAWINGS

The present invention is illustrated by way of example, and not limitation, in the figures of the accompanying drawings, in which:

FIGS. 1-6 illustrate plan (FIGS. 1, 3, and 5) and cross-sectional (FIGS. 2, 4, and 6) views of conventional RF MOSFETs in which respective pluralities of gate fingers, source fingers, and drain fingers are formed on a semiconductor structure.

FIGS. 7-12 illustrate plan (FIGS. 7, 9, and 11) and cross-sectional (FIGS. 8, 10, and 12) views of RF MOSFETs configured in accordance with various embodiments of the present invention.

FIG. 13 shows schematically an SOI wafer having a buried insulator layer according to an aspect of the present invention.

FIG. 14 shows schematically the wafer of FIG. 13 after further processing.

FIG. 15 illustrates the wafer of FIG. 14 after further processing.

FIG. 16 illustrates the wafer of FIG. 15 after further processing.

FIG. 17 illustrates a two dimensional section through a unit cell transistor aligned along the longitudinal axis of the device according to an aspect of the present invention.

FIG. 18 illustrate a semiconductor structure having, in sequence, a semiconductor substrate, a buried stressor layer, a thin bonding layer, a buried insulator layer, and an active semiconductor layer according to an aspect of the present invention.

FIG. 19 illustrates the semiconductor structure of FIG. 18 after further processing, with trenches having been etched through the thin bonding layer and buried stressor layer and into the underlying substrate.

FIG. 20 illustrates an example of a process for softening a silicon nitride hard mask in accordance with an aspect of the present invention.

FIG. 21 illustrates an example of a process for softening STI trench fill material in accordance with an aspect of the present invention.

FIG. 22 illustrates an example of a process to provide an SOI wafer consisting of a thin SOI layer over a thin BOX layer over a buried stressor layer on a silicon handle wafer in accordance with an aspect of the present invention.

FIG. 23 illustrates a composite structure consisting of, in sequence, a bulk donor wafer, a sacrificial thick BOX layer, a thin SOI layer, a thin BOX layer, a BS layer (with optional BL layer between the BS layer and the thin BOX layer), and a bulk handle wafer in accordance with an aspect of the present invention.

FIG. 24 illustrates removal of the donor wafer and sacrificial thick BOX layer of the composite structure shown in FIG. 23 to leave a thin SOI layer on a thin BOX layer on a BS layer (with an optional BL layer between the BS layer and the thin BOX layer) on a bulk handle wafer.

FIGS. 25 and 26 illustrate how the ordering of sources and drains of individual unit cell transistors of an RF MOSFET can be changed so that the order is reversed in every other cell in accordance with an aspect of the present invention.

### DESCRIPTION OF THE INVENTION

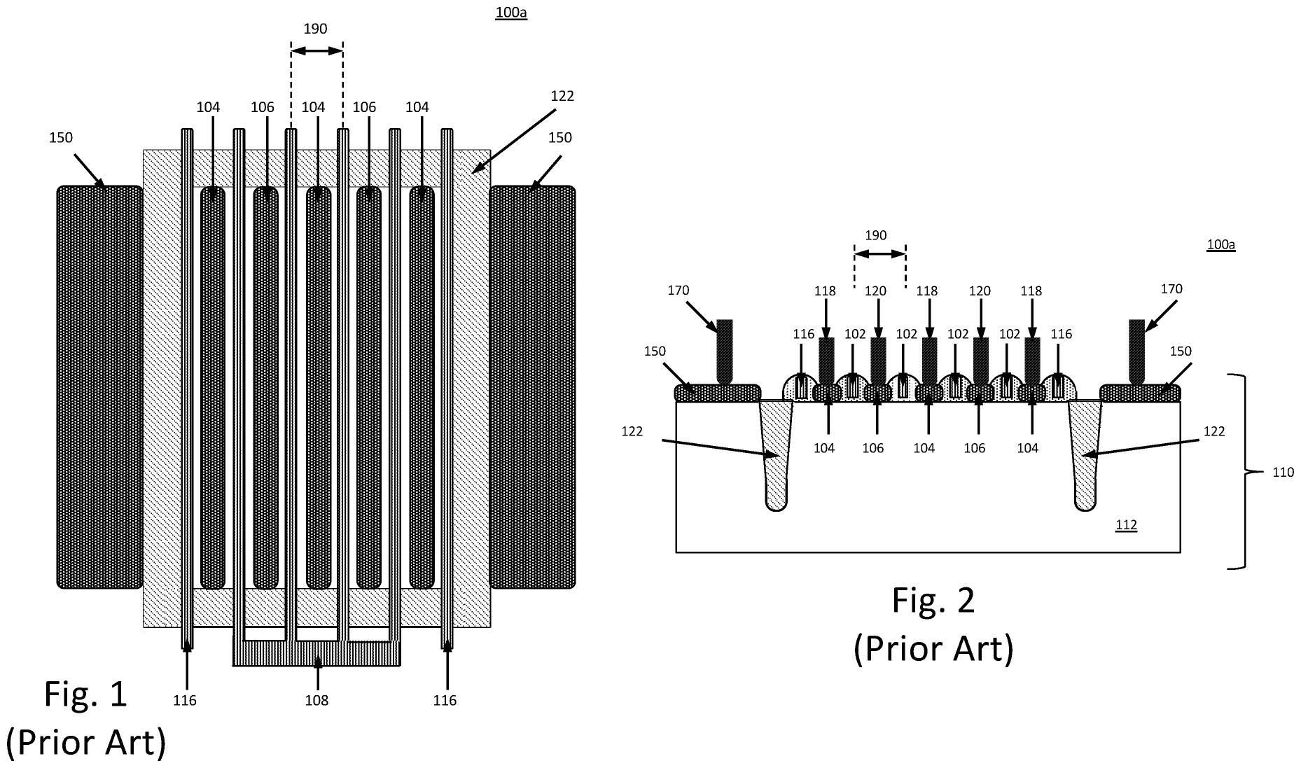

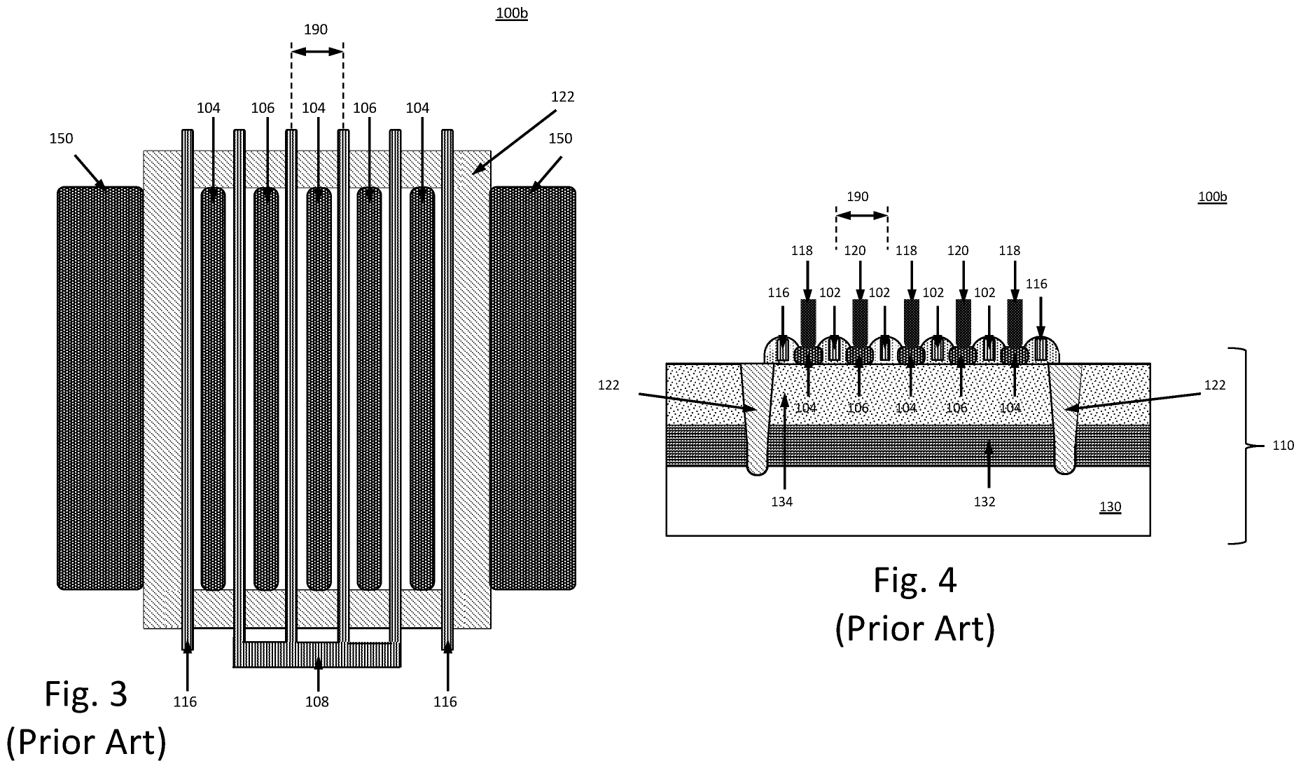

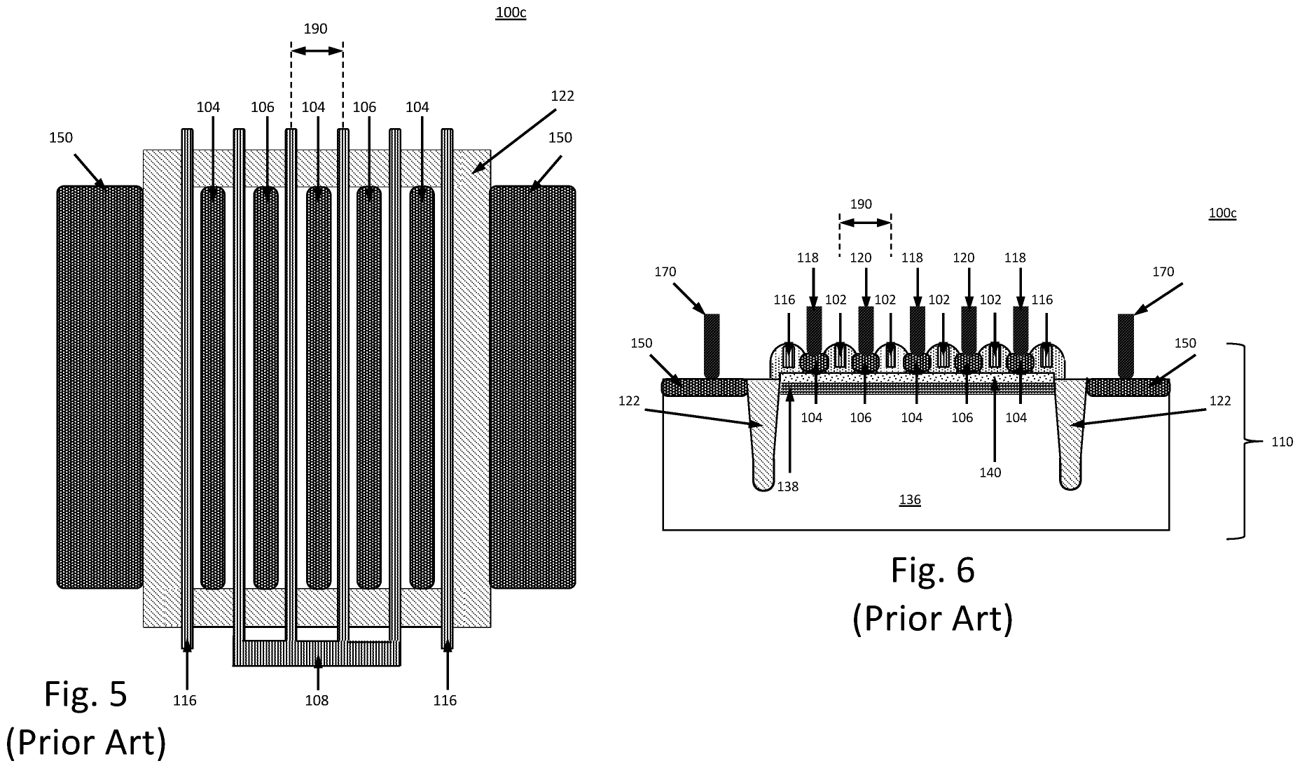

Referring to FIGS. 1-6, plan (FIGS. 1, 3, and 5) and cross-sectional (FIGS. 2, 4, and 6) views of conventional RF MOSFETs 100a, 100b, and 100c are shown. In RF MOSFETs 100a, 100b, and 100c, respective pluralities of gate fingers 102, source fingers 104, and drain fingers 106 are formed on a semiconductor structure 110. For RF MOSFET 100a, the semiconductor structure 110 is a bulk silicon wafer 112. For RF MOSFET 100b the semiconductor structure 110 is a PD-SOI wafer including a silicon substrate 130, a BOX layer 132 disposed over silicon substrate 130, and a partially depleted silicon layer 134 disposed over BOX layer 132. For RF MOSFET 100c the semiconductor structure 110 is an FD-SOI wafer including a silicon substrate 136, a BOX layer 138 disposed over silicon substrate 136, and a fully depleted silicon layer 140 disposed over BOX layer 138.

The gate fingers 102 are spaced apart from each other along a first direction (e.g., a longitudinal direction), extend in a second, orthogonal direction (e.g., a lateral direction), and are electrically connected to one another through a gate mandrel 108 which may be electrically connected to gate contacts (not shown). In some designs, gate mandrels are provided at both ends of the gate fingers to reduce the overall series resistance of the gate fingers. The source fingers 104 are spaced apart from each other along the first direction, extend in the second direction, and, although not shown in these views, are electrically connected to one another through a source mandrel or other structure which may be electrically connected to respective source contacts 118. The drain fingers 106 are spaced apart from each other along the first direction, extend in the second direction, and, although not shown in these views, are electrically connected to one another through a drain mandrel, which may be electrically connected to respective drain contacts 120. As illustrated, the respective source, gate, and drain fingers are interdigitated so that each gate finger 102 extends in the lateral direction between a pair of adjacent source and drain fingers 104, 106. The source and drain fingers typically comprise raised doped semiconductor regions that are grown epitaxially on the source and drain regions of the transistors. For example, in the case of NFETs, the source and drain fingers may be n-type doped epitaxial silicon or an alloy of silicon and carbon.

Electrically, each RF MOSFET 100a, 100b, and 100c is composed of a plurality of unit cell transistors electrically connected in parallel with one another. Such multi-cell RF transistors may find application in, for example, RF amplifiers, switches and the like. Each cell of a multi-cell RF transistor includes a gate finger 102, a source finger 104, and a drain finger 106, the source and drain fingers being on opposed sides of the gate finger, and the portion of the semiconductor structure 110 that underlies the gate, source and drain fingers. In the illustrations, the source fingers 104 and drain fingers 106 are portrayed as elevated epitaxial silicon source/drain regions and the actual sources/drains of each unit cell transistor (not shown) are located inside the silicon layer adjacent a channel region below a respective gate finger 102.

Each RF MOSFET 100a, 100b, and 100c is fashioned in a portion of semiconductor structure 110 between isolation trenches 122 and may be bounded by dummy gates 116, which may or may not be electrically connected to the gate mandrel 108. The distance between gate structures 102 is referred to as the contacted poly pitch (CPP) 190 and for conventional RF MOSFETs such as RF MOSFETs 100a, 100b, and 100c may be on the order of 100 nm. Contacts 170 to regions 150 formed on semiconductor structure 110 outside isolation trenches 122 allow for biasing the n-wells.

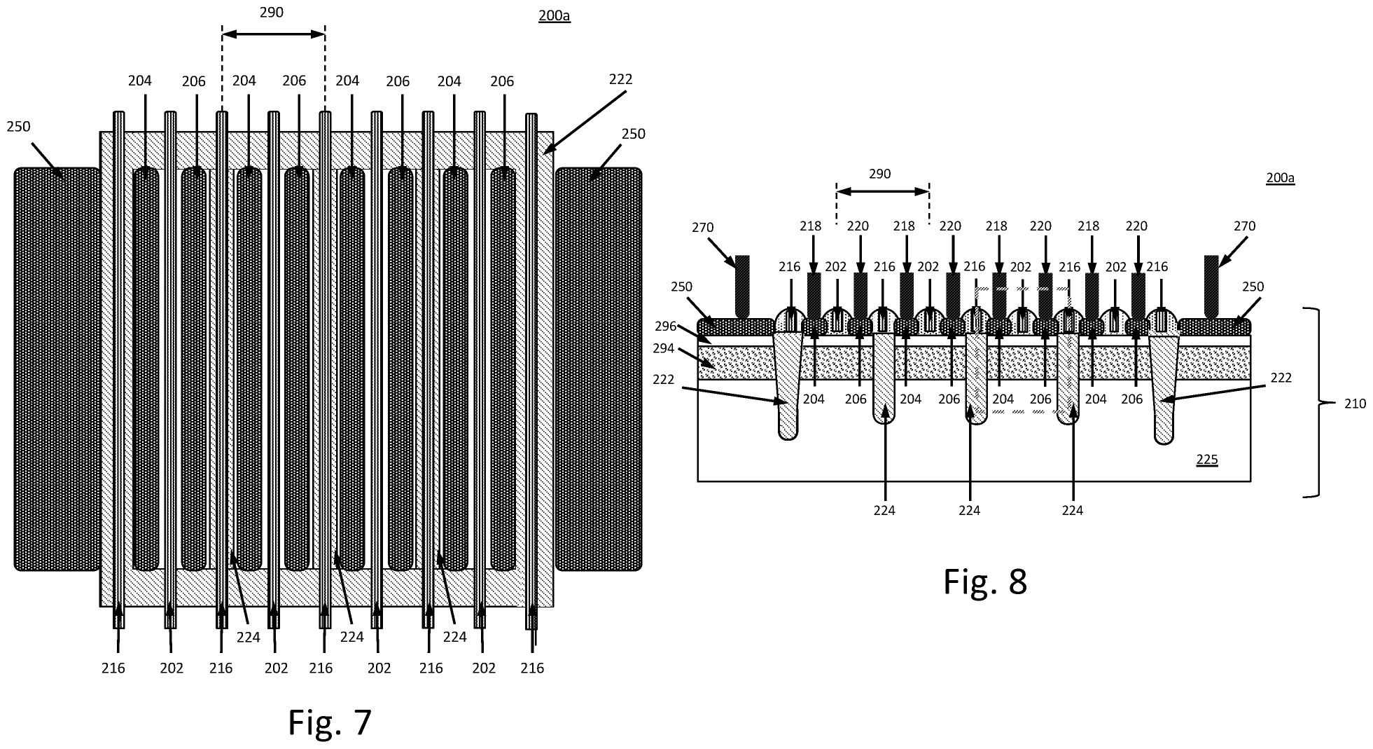

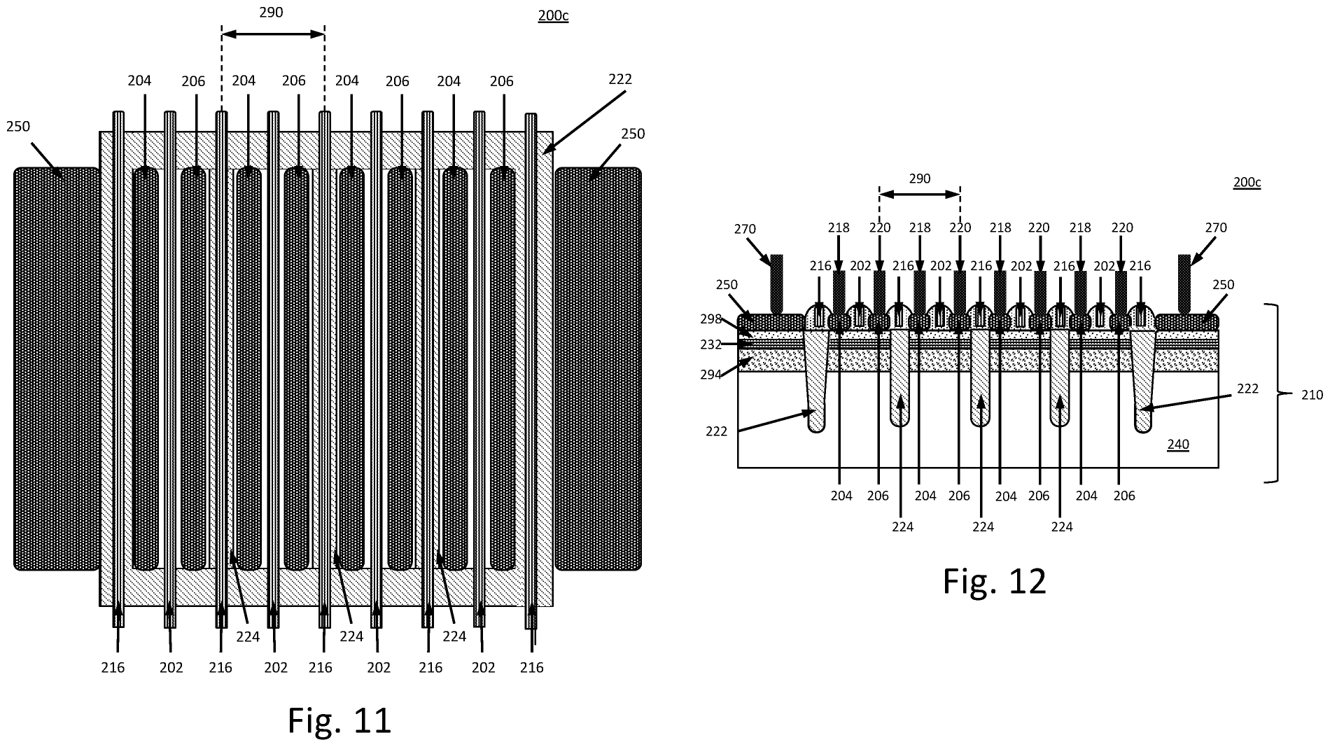

Now referring to FIGS. 7-12, plan (FIGS. 7, 9, and 11) and cross-sectional (FIGS. 8, 10, and 12) views of RF MOSFETs 200a, 200b, and 200c in accordance with various embodiments of the present invention are shown. In RF MOSFETs 200a, 200b, and 200c, respective pluralities of gate fingers 202, source fingers 204, and drain fingers 206 are formed on a semiconductor structure 210. For RF MOSFET 200a, the semiconductor structure 210 is a bulk semiconductor (e.g., silicon) substrate 212 with a buried stressor layer 294 disposed over the substrate 212 and a semiconductor (e.g., silicon) layer 296 disposed over the buried stressor layer 294. For RF MOSFET 200b the semiconductor structure 210 is a PD-SOI wafer including a semiconductor (e.g., silicon) substrate 230, a BOX layer 232 disposed over substrate 230, a semiconductor (e.g., silicon) layer 292 disposed over BOX layer 232, a buried stressor layer 294 disposed over the semiconductor layer 292, and a partially depleted semiconductor (e.g., silicon) layer 297 disposed over the buried stressor layer 294. For RF MOSFET 200c the semiconductor structure 210 is an FD-SOI wafer including a semiconductor (e.g., silicon) substrate 240, a buried stressor layer 294 disposed over the substrate 240, a BOX layer 232 disposed over buried stressor layer 294, and a fully depleted semiconductor (e.g., silicon) layer 298 disposed over BOX layer 232.

The gate fingers 202 are spaced apart from each other along a first direction (e.g., a longitudinal direction), extend in a second, orthogonal direction (e.g., a lateral direction), and are electrically connected to one another through a gate mandrel (not shown) which may be electrically connected to a gate contact (not shown). The source fingers 204 are spaced apart from each other along the first direction, extend in the second direction, and, although not shown in these views, are electrically connected to one another through a source mandrel or other structure which may be electrically connected to respective source contacts 218. The drain fingers 206 are spaced apart from each other along the first direction, extend in the second direction, and, although not shown in these views, are electrically connected to one another through a drain mandrel, which may be electrically connected to respective drain contacts 220. As illustrated, the respective source, gate, and drain fingers are interdigitated so that each gate finger 202 extends in the lateral direction between a pair of adjacent source and drain fingers 204, 206, but in MOSFETs 200a, 200b, 200c, the unit cell transistors 219 are separated from one another by a dummy gate 116 and trench 224, which trench extends into semiconductor structure 210 as further described below. The dummy gates are not electrically connected to the gate mandrel. The gate, source and drain fingers may each be made of a conductive material, such as a metal or a metal alloy, or polysilicon.

Electrically, each RF MOSFET 200a, 200b, and 200c is composed of a plurality of unit cell transistors 219 electrically connected in parallel with one another. Such multi-cell RF transistors may find application in, for example, RF amplifiers, switches and the like. Each cell of a multi-cell RF transistor includes a gate finger 202, a source finger 204, and a drain finger 206, the source and drain fingers being on opposed sides of the gate finger, and the portion of the semiconductor structure 210 that underlies the gate, source and drain fingers. In the illustrations, the source fingers 204 and drain fingers 206 are portrayed as elevated epitaxial silicon source/drain regions and the actual sources/drains of each unit cell transistor is located inside the silicon layer adjacent a channel below a respective gate finger 202.

Each RF MOSFET 200a, 200b, and 200c is fashioned in a portion of semiconductor structure 210 between isolation trenches 222 and may be bounded by dummy gates 216, which may not be electrically connected to the gate mandrel. The distance 290 between gate structures 202 is approximately twice the CPP 190 of RF MOSFETs 100a, 100b, and 100c, and may be on the order of 200 nm. Contacts 270 to regions 250 formed on semiconductor structure 210 outside isolation trenches 222 allow for biasing the n-wells.

In RF MOSFETs 200a, 200b, and 200c, buried stressor layer 294 may be, for example, SiGe or other buried stressor layer as described herein. In RF MOSFET 200a, trenches 224 preferable extend through semiconductor layer 296 and buried stressor layer 294 and into the underlying substrate 225 (e.g., n-type Si) 212. In RF MOSFET 200b, trenches 224 preferable extend through semiconductor layer 297, buried stressor layer 294, semiconductor layer 292, and into the BOX layer 232 and optionally partially into substrate 230. In RF MOSFET 200c, trenches 224 preferable extend through semiconductor layer 298, BOX layer 232, buried stressor layer 294, and into the substrate 240. As discussed below, trenches 224 allow buried stressor layer 294 to relax, thereby imparting strain to the overlying layer(s), e.g., BOX layer 232 and/or semiconductor layers 296, 297, 298, as applicable.

From FIG. 12 it should be apparent that particular implementations of the present invention may use an SOI wafer containing a compressively or tensilely stressed buried insulator structure. These compressively or tensilely stressed buried insulator layers and other implementations of compressively or tensilely stressed buried insulator structures may be regarded as stressed BOX structures or layers. Preferred SOI wafers including stressed BOX structures can advantageously be used to provide strained semiconductor regions and layers or to provide strained active regions within semiconductor device structures such as RF MOSFET 200c. Such structures are expected to achieve advantages of both strained silicon technology and SOI technology. The invention may be broadly applied to semiconductor on insulator wafers where the semiconductor is silicon or a material other than silicon, for example germanium, silicon germanium, silicon germanium carbon, gallium arsenide, gallium nitride, gallium phosphide, indium arsenide, indium phosphide, aluminum nitride, a III-V compound semiconductor, a II-VI compound semiconductor, silicon carbide, graphene, or a two-dimensional semiconductor such as molybdenum disulphide, tungsten diselenide or indium selenide. Devices manufactured in any of these semiconductor systems may benefit from tensile or compressive strain induced along one or more in-plane axes.

Additionally, as shown in FIG. 10, for PD-SOI RF MOSFETs, the buried stressor layer may be located within the semiconductor-on-insulator layer, above the BOX layer, not below it. In such instances, the isolation trenches between individual unit cell transistors typically would not necessarily extend through the BOX layer, although they may do so. And, the present invention is also applicable in cases where the wafers do not include a BOX layer, as shown in FIG. 8, and the buried stressor layer may be located immediately below the semiconductor layer in which the source/drain regions and the channel are formed.

In each case, preferred implementations of the invention form transistors, e.g., RF MOSFETs, by etching isolation trenches 224 as described above in order to allow the buried stressor layer to relax so that the overlying thin semiconductor layer will have tensile or compressive strain induced in-plane. The surface semiconductor layer may, in some embodiments, have a thickness of up to 50 nanometers. The relative amounts of strain directed along each of the primary axes of a semiconductor device (e.g., width and length) may be controlled independently through the spacing of the isolation trenches determined by the layout of the mask used to define the active area of the device. For example, where in-plane strain is not desired in the semiconductor along a particular axis in a semiconductor device, the trenches preferably are spaced sufficiently far apart along that axis such that the effect of the edge relaxation mechanism is suitably minimized. The trenches between unit cell transistors may be formed (e.g., etched) at the same time as the isolation trenches between RF MOSFETs or at different times. After etching, the isolation trenches subsequently may be filled with a suitable insulator (e.g., silicon dioxide) using any conventional trench isolation fill process. Preferably the trench fill is performed to maintain or achieve the desired strain properties of adjacent active regions.

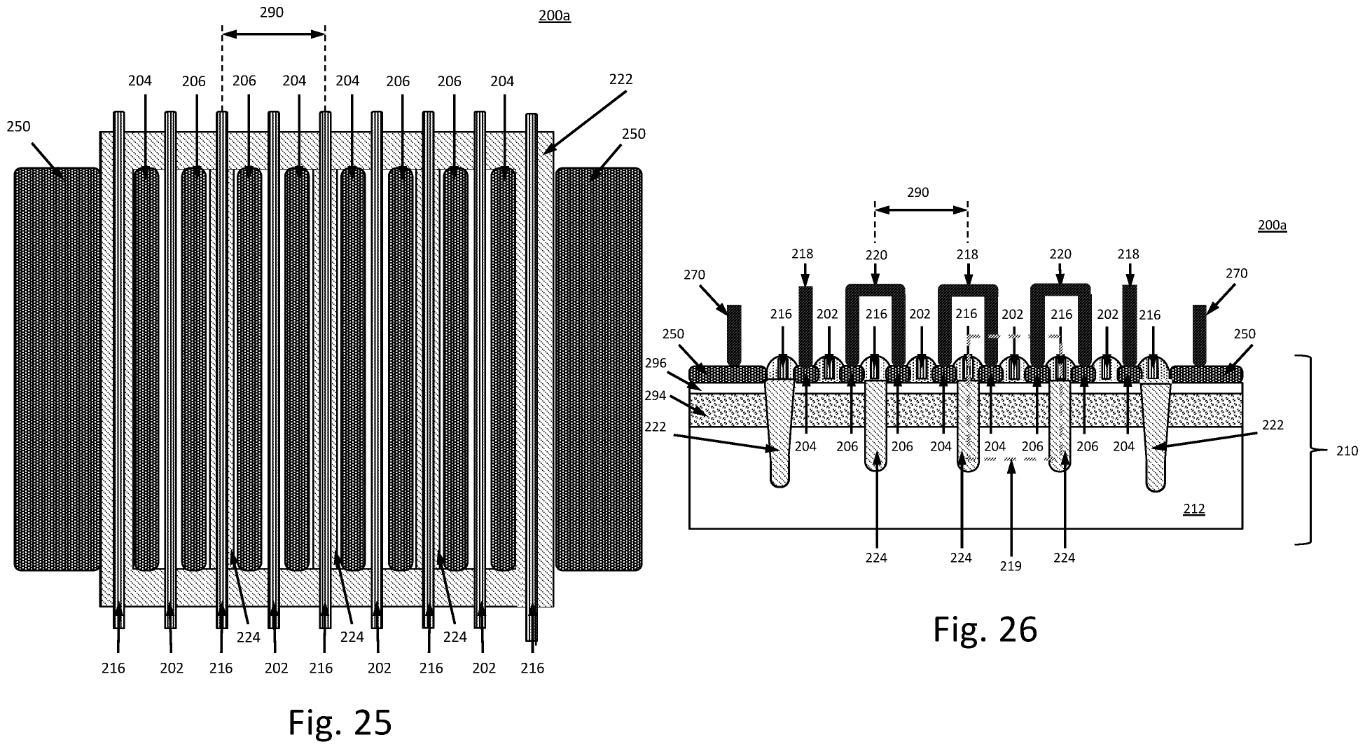

Although the separation of individual unit cell transistors of the present RF MOSFETs increases (approximately doubles) the CPP of conventional RF MOSFETs, the channel strain provided by the present invention improves performance of the present RF MOSFETs over their conventional counterparts by increasing the carrier mobility in the channel region under the gate (electron mobility in the case of n-channel MOSFETs). Additional benefits accrue from the modified layout, for example through lower source/drain resistance as each of the inner sources and drains is provided with current by a full dedicated contact, rather than sharing a contact with its neighbor. Additionally, in some embodiments of the invention, the ordering of sources and drains of individual unit cell transistors of the RF MOSFET can be changed so that the order is reversed in every other cell. An example is shown in FIGS. 25 and 26. In this example the ordering of sources and drains of individual unit cell transistors 219 is reversed for unit cell transistors adjacent one another and separated by a dummy gate 216. This allows interconnection of adjacent source contacts 218 or adjacent drain contacts 220, as applicable. This change of source/drain ordering in individual unit cell transistors of the RF MOSFET allows adjacent sources and drains to be electrically connected by the same metal interconnect. As such, the metal interconnect lines, whether they be in the first or second level of metal will be wider and consequently have lower series resistance.

By proper selection of an insulator layer, substrate, and a surface semiconductor layer, the surface layer may be tensilely or compressively strained in-plane and, where applicable, the insulator may be compressively or tensilely stressed. While silicon surface layers are particularly desirable in the context of RF FD-SOI and RF PD-SOI devices, it should be appreciated that the strategies, structures, and methods discussed here can be implemented in various systems, including tensile or compressive stressed systems, surface layers other than silicon, and insulators other than those specifically discussed here. Multiple layers may also be present on the substrate and surface semiconductor layer.

More generally, it is in some applications possible to use a buried layer, whether compressively or tensilely stressed, that is not an insulator. In this respect, it is possible that the structure that insulates the surface silicon layer from the substrate may incorporate a metal or conductive layer as part of the structure. It should nevertheless be appreciated that a silicon on insulator substrate or device is an especially preferred implementation of the present invention.

In-plane tensile strain can be created in a region of a thin layer of silicon by having an in-plane compressive stress in an underlying layer and etching closely-spaced isolation trenches through both layers. The thin layer of silicon preferably has a thickness of up to 50 nanometers and as little as 2 nanometers and the trenches preferably are etched deep enough to ensure that the layer with compressive stress is able to relax laterally by elastic edge relaxation. Consequently the stress is reduced in the compressive layer in proximity to the isolation trenches and in-plane tensile strain is induced in adjacent layers (above and below) in proximity to the isolation trenches, including in the thin silicon layer on top of the compressive layer. If the underlying layer with compressive stress is at least partially insulating, after etching isolation trenches, the region of isolated silicon on top can be used to fabricate an SOI device such as a fully depleted RF transistor. As discussed, this is readily achieved with appropriate stresses and geometry according to the present invention. As such, the method permits the fabrication of strained thin body SOI devices with potentially low cost and low defect densities compared to other contemplated methods.

For preferred implementations, the strain distribution laterally through a semiconductor surface layer between trenches is non-uniform and often may have a peak near a lateral midpoint between the trenches. Under some geometries, it is possible for the semiconductor surface layer to have a region adjacent its edge near a trench where the in-plane strain is near zero or has an opposite character (e.g., compressive instead of tensile) than the in-plane strain the layer is designed to receive.

U.S. Pat. No. 7,338,834 describes, among other things, a thin (less than critical thickness) epitaxial layer of silicon germanium grown on a silicon wafer under biaxial compressive stress and a thin layer of silicon grown epitaxially on top of the silicon germanium layer. When shallow trench isolation structures are formed, as in conventional CMOS processing, the compressive stress in the silicon germanium is relaxed elastically at the trench sidewalls and the adjacent silicon layer above the silicon germanium layer is caused to be under in-plane tensile strain over at least a part of the distance between the trench sidewalls. By controlling the separation of isolation trenches, which is the same as controlling the width or length of active areas, the amount and extent of tensile strain in the top layer of silicon may be adjusted independently in the width and length directions as preferred for the specific applications. Preferred methods and implementations of the present invention form active areas with strained silicon introduced by elastic edge relaxation, for example by forming appropriate trench isolation structures at desired separations on an SOI substrate that incorporates a stressed BOX structure.

Specific embodiments may make use of ion implantation to induce compressive stress in a buried layer of silicon nitride that may or may not have been in a state of stress before the ion implantation occurs. This particular embodiment of the method is favorable when the integrated circuit must be processed at high temperatures in the course of its manufacture, the high temperatures having the possible effect of reducing the built-in compressive stress in a layer of deposited silicon nitride. Ion-implant-induced stress may be implemented relatively late in the manufacturing process after stress-relieving high temperature steps, for example steps related to formation of the STI, have been completed. In addition, ion implant-induced stress may be applied selectively to a specific subset of transistors in an integrated circuit by use of an implant mask pattern formed lithographically in a layer of photoresist. For example, it may be preferred to only implant the silicon nitride underlying n-channel transistors in order to induce tensile strain in n-channels and avoid inducing tensile strain in p-channel transistors.

In another implementation of the invention a strained active layer is created by use of a thin layer of Ge or SiGe below the active layer. The wafer is prepared by depositing a compressively stressed layer of Ge or SiGe that is of less than critical thickness on a donor wafer followed by a thin layer of silicon and a thin BOX layer of silicon oxide. The thin BOX layer may be formed by thermal oxidation of at least a part of the thin layer of silicon. The BOX layer of the donor wafer is subsequently bonded to the product wafer, after which most of the donor wafer is separated by the SmartCut process as described in U.S. Pat. No. 7,534,701, leaving a thin and, at this point, unstrained silicon surface layer. The resulting wafer includes in sequence a silicon substrate, a layer of SiO₂ or other insulator having a thickness between 10 nanometers and 100 nanometers, a layer of Ge or SiGe of less than critical thickness, and the surface silicon layer of thickness between 4 nanometers and 50 nanometers. During fabrication of integrated circuits, isolation trenches are cut with appropriate spacings to relieve some of the stress in the buried Ge or SiGe layer, inducing the desired strain in the surface silicon layer.

In another implementation, a wafer includes sequential layers of a substrate, a layer of SiGe, an insulating layer, and a surface silicon layer. The SiGe layer is compressively strained as deposited. During fabrication of devices, isolation trenches are cut at appropriate spacing to relieve some of the strain in the SiGe layer, transmitting a stressing force to the overlying surface silicon layer through the insulating layer. Because the insulating layer separates the SiGe from the surface silicon layer, defects in the SiGe layer will not affect the surface silicon layer, so the amount of compressive stress in the SiGe layer is not limited to a critical thickness. The result is that the surface silicon layer in which devices are formed will be tensilely strained.

In embodiments having a stressed BOX structure comprising an in-plane compressively stressed silicon germanium buried stressor layer underlying an insulating layer of silicon oxide, the composition of the silicon germanium may be graded, starting with a low composition of germanium at the interface with the underlying silicon handle wafer and increasing with distance from that interface up to a higher level of germanium composition at the interface with the insulating layer of silicon oxide. The grading may extend over tens of nanometers and need not necessarily be linear. In a preferred embodiment, the germanium in the silicon germanium buried stressor layer is graded, increasing with distance from a low concentration between 0% and 20% at its interface with the underlying silicon handle wafer to a high concentration in the range of 50% to 100% at its interface with the insulating layer of silicon oxide. The grading of the germanium concentration is applied across a silicon germanium layer thickness of between 20 nm and 200 nm and most preferably between 40 nm and 100 nm. The high concentration of germanium at the interface with the silicon oxide layer may cause a high concentration of electrical defects at or proximate to that interface when fabrication of an integrated circuit is completed, and those defects may inhibit electrical conduction at that interface. A higher concentration of germanium at the bottom interface of the insulating layer of silicon oxide may cause a higher concentration of electrically active defects at that interface and consequently a greater inhibition of electrical conduction at or proximate to that interface in the finished integrated circuit.

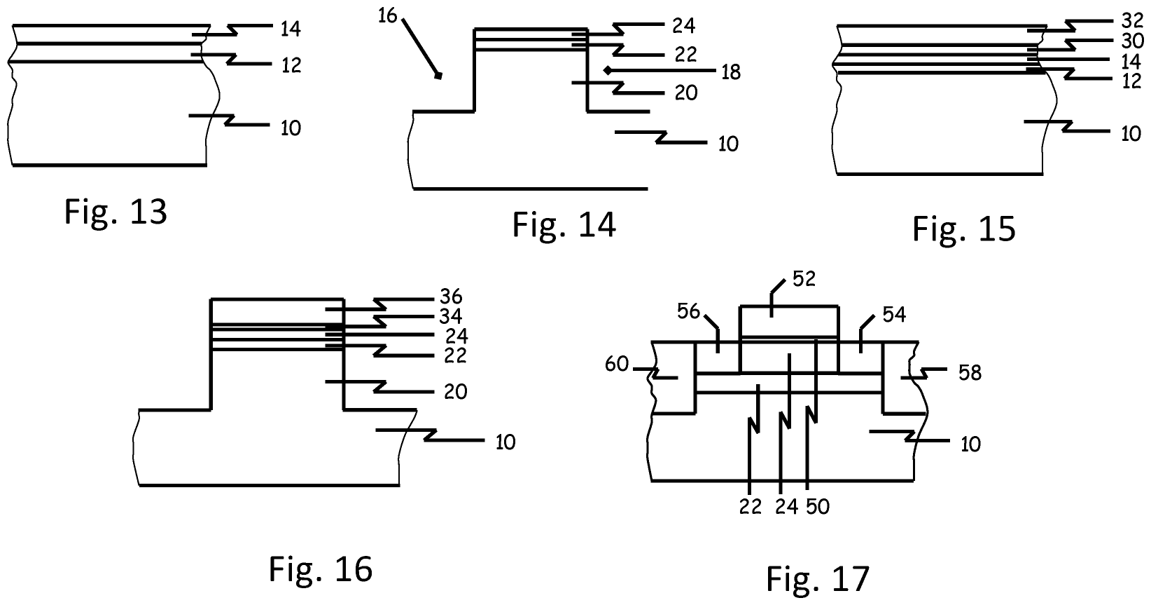

One implementation of the invention manufactures an SOI wafer or substrate with a built-in compressive stress in the buried insulator (BOX) layer. The compressive stress may derive from a structure consisting of or including a layer of silicon nitride which can be deposited conveniently by a chemical vapor deposition (CVD) method under conditions which give rise to built-in compressive stress. Such deposition conditions are very well known in the silicon IC processing industry. The SOI wafer preferably is fabricated using a wafer bonding method. The major difference in the processing described here, as compared to conventional bonded SOI processing, is that this processing forms a buried insulator (BOX) layer that contains a layer of material under compressive or tensile stress as depicted in FIG. 13 (so creating stressed BOX structure 12), rather than forming a conventional BOX layer consisting only of unstressed silicon dioxide. Aspects of the wafer bonding and layer definition process can be found, for example, in U.S. Pat. No. 6,372,609, to Wristers, et al., which is incorporated by reference here for these and its other teachings. The top surface semiconductor layer (layer 14 in FIG. 13 in which transistors will be fabricated is nominally unstrained when transistor fabrication begins and has a preferred thickness of between 2 and 50 nanometers.

The stress created in the substrate or wafer by the preferred stressed BOX structure is then relaxed in part to induce strain in portions of the surface semiconductor layer through preferred processes consistent with current CMOS processing. Normal CMOS IC processing uses trench isolation for device isolation and preferred embodiments take advantage of isolation trench formation to relax the stress in the BOX structure. Preferred processes etch isolation trenches through the stressed BOX structure and some distance into the underlying silicon or other substrate. When the trenches are etched, the compressive or tensile stress in the stressed BOX structure relaxes elastically at the edges of the active areas (i.e., at the trench sidewalls) and the at least partially relaxed BOX structure applies strain to the silicon on either side (i.e., above and below) of the stressed BOX structure over a certain distance extending away from the trench sidewall. As should be apparent, the stressed BOX structure generally is not fully relaxed by elastic edge relaxation and some amount of residual stress remains within the BOX structure. Here again, the BOX structure includes a buried insulator layer and a buried stressor layer or a buried insulator layer that is itself a buried stressor layer.

As noted above, U.S. Pat. No. 6,372,609 to Wristers, et. al. describes a buried silicon nitride layer under compressive stress but provides no mechanism for inducing strain in a silicon active region above the compressively stressed buried silicon nitride layer. By contrast, preferred implementations of the present invention preferably provide edge relaxation by forming trench isolation structures or other trenching. Forming trench isolation structures or other forms of trenching is preferred for introducing strain in individual transistors in a semiconductor device when the starting point for device fabrication is a wafer containing a buried insulating structure including a stressor layer throughout the wafer.

Preferably, the method described here etches trenches not only through the active layer and the stressed silicon nitride layer, but also into and possibly through the BOX layer and partially into the substrate. This frees the stressed nitride layer to expand (or contract) much more substantially into the isolation trench regions, generating substantial strain throughout the surface active silicon region.

The mechanism here is similar to that discussed in U.S. Pat. No. 7,338,834, entitled Strained Silicon with Elastic Edge Relaxation, incorporated by reference. U.S. Pat. No. 7,338,834 primarily describes the use of a silicon germanium buried stressor material that is grown epitaxially on a silicon or other substrate. In contrast, certain preferred BOX materials such as silicon nitride or silicon nitride layered with silicon oxide cannot presently be grown epitaxially and so cannot be accommodated in a simple manner. Preferred implementations of the present invention can make use of stressors that are not readily deposited (or grown) epitaxially. As a practical consequence, preferred implementations of the present invention can provide an insulating compressive or tensile stressed layer that may have many practical advantages including for cost and flexibility of manufacturing.

Some embodiments of the invention utilize silicon substrates and silicon active regions. However, the methods described here also may be used to fabricate devices having surface layers or substrates (or both) formed from semiconductor materials other than silicon including but not limited to germanium, silicon germanium, silicon germanium carbon, gallium arsenide, gallium nitride, gallium phosphide, indium arsenide, indium phosphide, aluminum nitride, a III-V compound semiconductor, a II-VI compound semiconductor, silicon carbide, graphene, or a two-dimensional semiconductor such as molybdenum disulphide, tungsten diselenide or indium selenide. The methods described here also allow for the surface semiconductor layer to be put under either in-plane tensile strain or in-plane compressive strain. Preferred implementations of the present invention etch trench depths deeper than the total thickness of the surface semiconductor layer and the stressed buried insulator layer, typically to a depth between about 300 nm and 400 nm, similar to what is practiced in state of the art bulk CMOS integrated circuit fabrication, although the depth of the trenches may be more or less. Etching these trenches is readily accomplished with conventional integrated circuit process technology. The present invention is particularly well suited to fully depleted ultra-thin body SOI applications because the transfer of stress into the overlying silicon layer is most effective when the silicon active layer is thin. The same principle of preferring thin surface layers applies to all of the non-silicon semiconductor materials referenced above, as well.

One stressor layer within a BOX structure with built-in compressive stress can be silicon nitride deposited with a built-in compressive stress. The stress may be in excess of one gigaPascal. The deposition conditions to achieve this are well known in the IC fabrication industry using commercially available equipment and processes. If the compressive layer is silicon nitride, it may be preferable to include thin layers of oxide on one or both faces of the compressive nitride layer where interfaces are formed to the top (active) silicon layer or the underlying silicon substrate wafer. Silicon oxide interfaces to silicon are likely to have bonding and electrical properties that are superior to those of silicon nitride interfaces to silicon.

In another embodiment of the invention compressive stress may be induced in a buried nitride layer by implantation of ions. Blanket implantation may be used to implant ions into or through all of a silicon nitride layer extending across a silicon wafer. Alternatively, the implantation of ions may be selectively applied to the nitride layer underlying some and not necessarily all of the transistors in a manufactured integrated circuit by implanting only the nitride layer under selected transistors with a moderate dose of ions. Inducing compressive stress in nitride regions by selective (masked) implantation may achieve the beneficial result that tensile strain is induced only in the overlying semiconductor layer of the selected transistors. In a particularly favorable embodiment with a silicon channel layer, tensile strain may be induced only in the channel layers of n-channel transistors and avoided in the silicon channel layers of p-channel transistors by using an implant mask defined photolithographically in a layer of photoresist and implanting only the silicon nitride layer underlying the n-channel transistor devices.

A silicon nitride buried stressor layer may be provided on a surface of a silicon wafer by wafer bonding techniques. For example, various methods for forming a buried stressed silicon nitride or silicon oxynitride layer by wafer bonding are described in U.S. Pat. No. 6,707,106. Direct bonding of semiconductor nitride surfaces has been described in U.S. Pat. No. 5,503,704 entitled “Nitrogen Based Low Temperature Direct Bonding,” in U.S. Pat. No. 5,904,860 “Method for Direct Bonding Nitride Bodies” and in several articles including Bower et al., “Low Temperature Si₃N₄ Direct Bonding,” App. Phys. Letts., vol. 62, pp. 3485-3487 (1993), Yi, et al., “Systematic Low Temperature Silicon Bonding using Pressure and Temperature” Jap. J. Appl. Phys., vol. 37, pp. 737-741 (1998) and Harendt, et al., “Silicon Fusion Bonding and Its Characterization” J. Micromechanical Microengineering, vol. 2, pp. 113-116 (1992). U.S. Pat. Nos. 5,503,704 and 5,904,860 are incorporated by reference for their teachings with respect to direct bonding of wafers via silicon nitride layers.

It is desirable to preserve built-in stress in the buried silicon nitride (or other) stressor layer so that it may be utilized to induce strain in an overlying semiconductor layer when trenches are etched. Consequently, it is preferable that the direct bonding of silicon nitride to a silicon or other wafer be performed at a sufficiently low temperature to maintain the built-in stress (whether compressive or tensile) in a direct bonded silicon nitride layer. Spontaneous bonding of silicon wafers coated with silicon oxynitride or silicon nitride layers can occur if the surface roughness of the oxynitride or nitride layers is lower than 0.5 nm (RMS).

Furthermore, using a silicon nitride bonding layer, it is possible to produce semiconductor-on-insulator wafers where the host wafer is silicon and the top semiconductor layer is other than silicon. An example of such heterogeneous semiconductor-on-insulator with buried nitride is suggested in Miclaus, et al., “Wafer Bonding of (211) Cd_{0.96}Zn_{0.04}Te on (001) Silicon,” J. Electron. Materials, vol. 32, pp. 552-555 (2004). The Miclaus article describes bonding of a compound semiconductor layer on a buried silicon nitride insulator layer but does not describe any method for inducing strain in the compound semiconductor layer. The bonding strategy of the Miclaus, et al., article can be included with the strain and edge relaxation strategies described here to induce strain in compound semiconductor materials including group II-VI materials such as cadmium telluride, cadmium-zinc telluride and mercury cadmium telluride and group III-V materials such as gallium arsenide, indium gallium arsenide, indium phosphide, indium gallium arsenide, gallium nitride, indium gallium nitride and aluminum nitride.

In certain embodiments, a BOX structure may be made from a compressively or tensilely stressed silicon nitride layer having a silicon dioxide layer on one or both of its upper and lower faces. If a silicon oxide layer intervenes between the stressed silicon nitride and the top semiconductor active layer, the silicon dioxide-semiconductor interface may have superior electrical properties in comparison with a silicon nitride-semiconductor interface. On the other hand, the stress induced in the top semiconductor layer by edge relaxation may be reduced if the intervening silicon dioxide layer acts as a stress buffer due to its inherent mechanical compliance and lowered viscosity during high temperature anneal cycles. Therefore in some circumstances it may be preferred to have the buried silicon nitride layer in direct contact with the uppermost semiconductor active layer. In other embodiments an insulating material other than silicon dioxide and having a stiffness greater than silicon dioxide may be inserted between the stressed silicon nitride layer and the surface active semiconductor layer. Insulating materials with high Young's Modulus (equivalently low compliance) and good electrical insulation properties include aluminum nitride, aluminum oxide, hafnium oxide, hafnium oxynitride, all of which may be deposited by known chemical vapor deposition (CVD) or atomic layer deposition (ALD) techniques. Compared with a Young's Modulus for silicon nitride which may be between 200 and 320 GPa depending on the deposition and treatment conditions for the silicon nitride thin film, aluminum nitride and aluminum oxynitride have bulk moduli of 200 GPa and 206-214 GPa respectively and aluminum oxide has an elastic modulus reported to be between 150 and 180 GPa. ALD hafnium oxide HfO₂ thin films and ALD aluminum oxide Al₂O₃ thin films have been measured to have an elastic modulus of between 180 GPa and 260 GPa. In general, insulating materials with a Young's modulus in the range 150 GPa to 250 GPa are preferred for a dielectric layer between the buried silicon nitride stressor layer and the surface active semiconductor layer.

A preferred method for fabricating a buried silicon nitride layer in direct contact with a top semiconductor active layer follows. In an exemplary process, a high quality silicon nitride thin film may first be formed on the surface of a donor silicon wafer by thermal nitridation, for example using a plasma source of free nitrogen atoms or a molecular nitrogen source such as ammonia (NH₃) and heating to a high temperature in the range 300° C. to 1050° C. and then a stressed silicon nitride or oxynitride layer may be subsequently deposited, followed by deposition of a thin film of silicon oxide. The purpose of a high quality nitride thin film is to provide a suitably high quality interface with low interface defect and trap densities between the silicon nitride and the silicon which is a desirable condition for good performance and reliability of MOS transistors subsequently fabricated in close proximity to the interface. The layered silicon-silicon nitride-silicon oxide wafer so formed may then be bonded to a silicon handle wafer using a standard method for wafer bonding involving a combination of applied pressure and thermal annealing as widely practiced in the semiconductor industry and described above, including in the above-incorporated U.S. Pat. No. 6,707,106. The silicon handle wafer may optionally have a silicon oxide layer formed upon it before the wafer bonding is performed to facilitate or improve the bonding process. Subsequently a majority of the donor wafer may be removed by a standard wafer separation process, such as the Smart Cut process employed by SOITEC, leaving a thin layer of silicon of desired thickness attached to the silicon nitride layers. U.S. Pat. No. 6,372,609 is incorporated by reference for its teachings with respect to processing buried insulating layers.

As discussed above, a preferred process for forming a BOX may include forming a high quality silicon nitride layer followed by depositing a compressively or tensilely stressed silicon nitride layer, followed by depositing a silicon oxide layer. Depositing the stressed silicon nitride layer may be accomplished, for example, by plasma enhanced chemical vapor deposition (PECVD) or low pressure chemical vapor deposition (LPCVD) process. By varying input factors in the CVD process, predictable amounts of either tensile or compressive built-in stress in the range 1.7 gigaPascal tensile to −3.0 gigaPascal compressive can be selectively incorporated in a deposited silicon nitride thin film. For example, Arghavani, et al. “A Reliable and Manufacturable Method to Induce a Stress of >1 GPa on a P-Channel MOSFET in High Volume Manufacturing,” IEEE Electron Device Letters, Vol. 27, No. 2, 114-116 (2006) describes how a silicon nitride thin film with tensile built in stress of 1.2 GPa may be formed by LPCVD and a silicon nitride thin film with compressive built in stress of close to −3.0 GPa may be formed by PECVD. Furthermore, close to a 2.0 GPa tensile stress value can be achieved with UV cured LPCVD silicon nitride films.

Alternatively the layer with compressive stress may be a metal deposited with built-in stress formed by any known conventional method such as sputtering under low gas pressures typically in the range 0.1 milliTorr to 10 milliTorr. The metal layer with built-in compressive stress may be tungsten, molybdenum, titanium or an alloy of those metals or a metal compound such as a nitride of W, Mo or Ti, a silicide of W, Mo, Ti, Co or Ni or a boride of Hf or La. If the layer with compressive stress is a metal, the layer most preferably is electrically isolated from the top layer of silicon (or other semiconductor) by ensuring a thin insulating layer such as silicon dioxide is interposed between the metal and the silicon (or other) surface layer.

Preferred methods and implementations may deposit silicon nitride with built in compressive stress as the stressor layer within the stressed BOX structure. Preferred methods for creating and using the stressed BOX structure may deposit thin oxide layers both before and after deposition of the silicon nitride on the host wafer prior to the wafer bonding process. This particularly preferred stressed BOX structure provides silicon oxide layers, thin in comparison to the nitride layer, on either side of the silicon nitride layer to avoid direct contact between the nitride layer and adjacent silicon layers. In addition, it may be preferable to bond the active silicon layer to an oxide surface rather than a nitride surface.

Particularly preferred implementations deposit stressed silicon nitride on both sides of the host silicon wafer so as to avoid wafer bending by providing equivalent stresses on either side of the host wafer. It is desirable to maintain a flat wafer through both (a) the SOI bonding process and (b) the lithography process which defines the active areas and corresponding isolation trench pattern. With nitride on both faces of the silicon wafer, there will be stress balance, ensuring that wafer bowing is avoided or at least limited. After etching the isolation trenches to accomplish edge relaxation and hence induce strain in the surface semiconductor layer, preferred implementations etch the stress balancing silicon nitride layer off the back face of the silicon or other wafer because the stress on the front face will be released in large part by the trenches and therefore after etching the trenches a balancing stress on the reverse face is generally not required and generally not desired.

Other implementations of an SOI substrate with a stressed BOX structure use deposited conductive thin films with built-in compressive stress as the stressor layer in the stressed BOX structure. For example, the stressed BOX structure may consist of an embedded layer of compressively stressed electrically conductive material, encapsulated with insulator on one or both sides. Refractory metals such as tungsten, molybdenum and titanium or their alloys can be deposited with built-in compressive stress conveniently by using sputtering methods under conditions which are well known in the CMOS IC processing industry. The choice of stressed metal is restricted by the requirement that it be sufficiently chemically and physically stable to withstand the thermal budget and thermal shocks associated with the CMOS IC fabrication process. Other options for the embedded stressed conductive layer include metal borides (such as LaB₆, HfB₂) and metal carbides (such as HfC) and metal nitrides (such as HfN, TaN and TiN). Another alternative is to deposit a layer of undoped amorphous silicon and heavily dope the layer by high dose ion implantation of arsenic atoms then subsequently anneal the wafer to activate the arsenic and convert the amorphous silicon to polycrystalline silicon which will consequently be under compressive stress.

If a compressively stressed conductive layer is embedded in the BOX so as to create a stressed BOX, the conductive layer may subsequently be utilized as a back gate for SOI transistors fabricated over the BOX structure.

Another preferred method and implementation uses as a buried stressor a layer of Ge or SiGe of less than critical thickness, as defined in U.S. Pat. No. 7,338,834. A first method is to prepare a wafer in which a layer of Ge or SiGe of less than critical thickness is provided between a silicon layer and a BOX covering a silicon substrate.

An initial step in this implementation deposits a Ge or SiGe layer of less than critical thickness on a silicon handle wafer. The Ge or SiGe layer is compressively strained in the surface plane of the wafer and there are very few or no dislocations since the Ge or SiGe thickness is purposely of less than critical thickness specifically to minimize or eliminate dislocations. After the Ge or SiGe layer is prepared, it is bonded to a donor wafer, which consists of a layer of SiO₂ (or other insulator) on a silicon substrate. The process proceeds by removing all but a thin active silicon layer from the donor wafer using known methods such as the Smart Cut process.

At this stage, the silicon active layer will be substantially unstrained. After the Smart Cut split occurs, the receiving (final) wafer will tend to push out at the edges since the Ge or SiGe will be able to expand somewhat. This is because the thin remaining active layer of silicon (5 to 20 nanometers) will not have sufficient force to fully restrain the compressed Ge or SiGe, and the BOX is also compliant enough to allow a small amount of expansion of the Ge or SiGe near the wafer edge. In the interior of the wafer the Ge or SiGe will retain most of its initial strain. Consequently, in the interior of the wafer, the active silicon layer will have very little strain until after trench formation. Modeling of the strain shows that the wafer edge relaxation will fully dissipate for the area of the wafer that is more than 500 nm from the edge. For a 300 mm wafer, a negligible portion of the surface silicon will be strained.

The wafer is further processed to construct devices. The further processing includes cutting isolation trenches with appropriate spacing to induce tensile strain in the active silicon layer as the Ge or SiGe layer expands into the voids created by the cutting of the isolation trenches through edge relaxation, as discussed above.

For future devices with a very thin active silicon layer that can provide a fully depleted condition, a thin layer of Ge, possibly of a thickness of less than 5 nanometers, may be desirable, and may induce a useful amount of stress. For thicker active layer, a layer of SiGe of less than critical thickness may be more desirable.

Another implementation places a layer of SiGe on the receiving substrate and then proceeds to create a silicon active layer with a buried insulator above the SiGe layer. This process creates an SOI wafer in which a layer of SiGe is positioned between the buried insulator and the silicon substrate. The SiGe layer will be compressively strained, and may be of greater than critical thickness. This contrasts with other methods discussed here, and in U.S. Pat. No. 7,338,834, in which care is taken to avoid dislocations by ensuring that the SiGe layer is of less than critical thickness. The reason the thickness can be greater than the critical thickness in this case is that the insulating layer is interposed between the SiGe layer and the overlying active silicon layer, so dislocations in the SiGe layer are not propagated to the overlying silicon layer. Fabrication of devices includes forming isolation trenches, as discussed in more detail elsewhere in this application. This allows the SiGe layer under the BOX to expand. This in turn transmits a tensile strain force to the active silicon layer through the BOX.

If the BOX is heated above a threshold temperature during subsequent processing, it may soften and possibly begin to flow. When the BOX is heated and softens, the tensile strain induced in the active silicon layer may be reduced as the viscous layer of silicon dioxide mechanically decouples the stressor layer from the overlying active silicon layer. If the BOX is silicon dioxide, the upper limit of the temperature that does not cause softening is about 850° C. Other insulating materials that might be used for the buried insulator may have more desirable thermal properties.

If the isolation trenches are filled with a material that binds to the silicon active layer and is of low compliance, then some of the strain induced from the SiGe layer below the BOX structure will be retained even if the BOX itself softens in subsequent processing after the isolation trenches are filled.

Forces creating stress are generally additive, and the SiGe under BOX method may be practiced in combination with other methods of creating stress that lead to a favorable strain condition in the active region of a semiconductor device, such as the channel region of a MOSFET.

Following formation of a desired SOI substrate having a BOX structure that is compressively stressed in the plane of the wafer, a further preferred process then etches trenches according to a trench isolation process. The trenches define device active regions, including channels of individual unit cell transistors, in the surface silicon layer. Most preferably, the trenches are positioned so that the active regions have a lateral extent (e.g., an active length, sometimes denoted as “RX”) that is sufficiently small that relaxation can occur across the entire lateral extent of the stressed BOX structure between the trenches. The lateral extent may be less than about 500 nm or, more preferably, between about 100 nm and 250 nm. As soon as the trenches are cut, and without further treatment, the compressive strain in the stressed BOX structure is able to partially relax, most advantageously in an elastic process, which induces substantial tensile strain in the surface silicon layer. Those of ordinary skill in the art will appreciate that in many modern configurations, active device regions may be surrounded by a continuous set of interconnected trenches. Even though such a set of interconnected trenches (e.g. the combination of multiple interconnected trenches 222 and 224 in FIGS. 7, 9, 11 and 25), may be viewed as a single trench, for clarity, the present discussion refers to the etched openings on opposite sides of an active region as different trenches.

The new boundary formed at the surface of the trench sidewall allows the in-plane compressively stressed BOX structure to extend outwards and in so doing to induce a tensile strain in the adjacent silicon lattices above and below the stressed BOX structure. Thus, an in-plane tensile component of strain may be obtained in the overlying silicon layer. The tensile strain induced into the top silicon layer by this method may in general be non-uniform in its distribution but is of sufficient magnitude to improve the in-plane electron mobility to a desirable extent and hence to improve the electrical performance of n-channel transistors having channels formed in the layer.

FIG. 13 illustrates in schematic cross section a substrate 10 having a BOX structure 12 and a surface semiconductor layer 14 formed by any of the strategies discussed above. Also as discussed above, the materials of substrate 10, BOX structure 12 and surface semiconductor layer 14 may be selected broadly in accordance with aspects of the present invention but will be described here in terms of a particularly preferred embodiment having a silicon substrate 10, a BOX structure 12 including a stressed SiGe layer and at least one oxide buffering layer and a surface silicon layer 14. Following formation of a preferred SOI wafer as illustrated in FIG. 13, a preferred process continues by etching trenches 16, 18 through the layers 14 and 12 and into the substrate 10 to a sufficient depth and with the trenches sufficiently closely spaced to allow edge relaxation to induce strain over a major portion of surface semiconductor layer 14. The end result of this process is illustrated in FIG. 14. The illustrated trenches 16, 18 can be formed using the processing typically used for trench isolation structures and preferably are formed to extend through the stressed BOX structure and partially into the underlying silicon substrate 10. As noted above, the trenches may be different portions of a continuous network of trenches. The sidewalls of the trenches define a surface region 20 of the substrate, a stressed BOX structure 22 on the substrate surface region 20, and a strained surface silicon layer 24 on the stressed BOX structure 22. Each of the region 20, layer 22 and layer 24 extend between the sidewalls of trenches 16 and 18. As discussed above, etching the trenches most preferably allows the stressed BOX structure 22 to relax and to induce in-plane tensile (or compressive) strain within the silicon layer 24 above the etched BOX structure 22.

In embodiments having a stressed BOX structure comprising an in-plane compressively stressed silicon germanium buried stressor layer underlying an insulating layer of silicon oxide, the composition of the silicon germanium may be graded, starting with a low composition of germanium at the interface with the underlying silicon handle wafer and increasing with distance from that interface up to a higher level of germanium composition at the interface with the insulating layer of silicon oxide. The grading may extend over tens of nanometers and need not necessarily be linear. In a preferred embodiment, the germanium in the silicon germanium buried stressor layer is graded, increasing with distance from a low concentration between 0% and 20% at its interface with the underlying silicon handle wafer to a high concentration in the range of 50% to 100% at its interface with the insulating layer of silicon oxide. The grading of the germanium concentration is applied across a silicon germanium layer thickness of between 20 nm and 200 nm and most preferably between 40 nm and 100 nm. The high concentration of germanium at the interface with the silicon oxide layer may cause a high concentration of electrical defects at or proximate to that interface.

The distribution of strain in the various layers following trench formation is inhomogeneous and the final strain distribution is strongly dependent on the geometry of the layered structures. Another consideration in determining the strain within a completed device is the material used to fill the etched trenches and the processes for etching and for filling the trenches. In most conventional trench isolation CMOS processes, the trench is first lined with a thermal oxide (a silicon oxide grown at high temperature in an oxidizing ambient) and then fill material (typically silicon dioxide) is deposited and, in some cases, annealed. This fill technology generally gives rise to additional compressive strain in the system which may be transferred into the active layer. Linear superposition principles apply to stresses, so if the conventional trench isolation fill scheme is employed, it may similarly impose an additional compressive component on top of the tensile strain in the silicon layer. Overall, the net strain in the active silicon layer will be more tensile when a compressive stressor layer is present below the active silicon layer. Furthermore, as is known in the art, it is possible to minimize the compressive stress induced by the trench isolation structure fill process by modifying the process conditions for the liner, dielectric fill and densification anneal, when such an anneal is used.

One manufacturing process according to the present invention involves forming trenches into an SOI substrate having a stressed BOX structure beneath a thin relaxed silicon surface layer. In conventional trench isolation technology, a hard mask (typically silicon nitride) is employed to pattern the trenches. Starting from the silicon substrate 10, stressed BOX structure 12 and silicon surface layer 14 structure illustrated in FIG. 13, a process may form a pad oxide layer 30, typically by thermal oxidation or chemical vapor deposition (CVD), followed by depositing a silicon nitride layer 32 by CVD in the manner illustrated in FIG. 15. Both the silicon nitride 32 and pad oxide 30 layers are patterned to form masking oxide 34 and nitride hard mask 36. Etching using the nitride mask 36 as a hard mask forms the structure illustrated in FIG. 16. The nitride mask 36 serves not only as a mask to the reactive ion etch (RIE) used to etch the trenches but also as a hard stop to the chemical mechanical polishing (CMP) used to planarize the silicon dioxide that fills the trenches. Because of this, the conventional trench isolation process leaves the patterned nitride 36 and oxide 34 mask in place until after planarization of the trench filling material is completed.

On the other hand, leaving the nitride hard mask 36 in place may inhibit the elastic strain relief when the trenches are etched, tending to cause the compressive strain to be retained in the etched stressed BOX structure 22 and the surface silicon layer 24 to not be strained to a desirable extent. In some embodiments then, the trench isolation process is modified to more efficiently allow elastic relaxation. Possible modifications include using a nitride trench isolation structure liner or a more compliant pad oxide. For example, after the isolation trench etch is completed, the nitride hard mask can be removed. Preferably the hard mask is removed and elastic strain relaxation is allowed to take place uninhibited. Then a thinner nitride “liner” layer is deposited conformally over the isolation trench topography. This silicon nitride liner layer is used as the polish stop for the CMP planarization used after depositing an insulator such as silicon dioxide using, for example, high density plasma chemical vapor deposition. The nitride layer is subsequently removed from the top surface of the active area by a suitable etch process and remains on the trench sidewalls and the trench bottom.

Further processing is preferably performed to form n-channel devices and, as desired, p-channel devices. An example of a portion of a device is illustrated in FIG. 17 which represents a two dimensional section through a unit cell transistor aligned along the longitudinal axis of the device. As shown, the partially relaxed stressed BOX structure 22 is provided over the substrate 10 and the strained silicon surface layer 24 covers the BOX structure 22. For this n-channel device, gate dielectric 50 separates gate electrode 52 from the silicon surface layer 24. n-type source and drain regions 54 and 56 are provided on either end of the layer 24 so that the silicon surface layer 24 acts completely or at least partially as the channel region of the illustrated device. In the illustrated configuration, shallow trench isolation structures 58, 60 are formed at the ends of the source and drain regions 54, 56.

In some implementations, effective edge relaxation may be judged as inducing a level of stress of at least 200 megaPascal at some point over the span of a silicon surface layer between two trenches. Other material systems will have different preferred levels of stress. Effective edge relaxation can alternately be judged in some circumstances as developing a desirable level of stress in a surface layer across a major portion of a transverse lateral extent of a surface layer. In some implementations, a major portion may be judged as being fifty percent or more than fifty percent. In particularly preferred implementations, whether in these on in other embodiments discussed here, effective edge relaxation may be evaluated as inducing stress in a surface silicon layer of greater than 200 megaPascal over a transverse lateral extent of more than fifty percent of the transverse lateral extent width of a silicon surface layer.

In another embodiment of the invention, compressive stress may be induced in a buried nitride layer by implantation of ions. A buried silicon nitride layer is created, for example by wafer bonding or other method such as described above, but in a comparatively unstressed or a tensile stressed state. Processing continues until it is appropriate to induce stress, for example after isolation trench formation. A dose of ions of elements such as phosphorus, boron, carbon, germanium, silicon, arsenic, antimony, argon or oxygen is implanted with an areal dose in the range 1×10¹³ to 1×10¹⁵ ions per square centimeter and at an energy suitable to position the peak of the implanted ion distribution at a depth approximately midway between the top and the bottom of the buried nitride layer. Oxygen and germanium are presently particularly preferred ions to implant into or through a silicon nitride thin film in order to induce stress, which may include increasing the level of compressive stress or by reducing the level of tensile stress in a layer that has existing stress. Future implementations may favor other ions for inducing stress or altering the level of stress in a layer. Blanket implantation may be used to implant ions into or through the whole of a silicon nitride layer extending across a silicon wafer. Alternatively, the implant may be applied selectively to regions of the silicon nitride layer underlying a selected portion of the devices in a manufactured integrated circuit with the result that tensile strain is induced only in the overlying semiconductor layer of the selected transistors. Selective implantation of the nitride underlying target transistors can be achieved by using a select mask for the implant step, the select mask being defined for example lithographically in a layer of photoresist.

Before performing ion implantation to induce a net compressive stress in a buried silicon nitride layer, the silicon nitride may have approximately zero built-in stress or optionally may have tensile built-in stress. After implantation the buried nitride may be under compressive stress or have a negligible total stress. This method may be preferred for example to induce tensile stress only in the channels of n-channel transistors by using a suitable ion implant mask and inducing compressive stress through implantation of ions only into the buried nitride underlying n-channels while avoiding inducing compressive stress in the nitride layer underlying p-channel transistors. The compressive stress induced by implantation can be used to offset a previously existing tensile stress in a nitride region or can be used to induce a compressive stress in a nitride that does not previously have a significant built-in stress. Other processing is performed, for example as discussed above, with the implantation advantageously performed at an appropriate point in the device fabrication process such as following trench formation or after most or all high temperature processing steps for the integrated circuit have been completed.

A challenge in the production of SOI wafers and devices based on such structures with buried stressor (BS) layers beneath the oxide arises if the BS layer does not provide an ideal surface for bonding. Silicon is a very satisfactory material for a handle wafer and methods are well established for obtaining complete bonding of an oxide layer with silicon with few or no bond defects. Pre-conditioning treatments are known that ensure reproducible, low-defect, bonded interfaces of high quality. Such treatments include wet chemical cleans or surface modifications and plasma surface conditioning. A buried stressor layer such as silicon germanium, on the other hand, may present difficulties in bonding, for example arising from the poor chemical stability of germanium oxide relative to silicon oxide or from precipitation of germanium atoms at the surface of the SiGe layer prior to bond formation.

SOI wafers with bonding layer between buried oxide and buried stressor layer:

Because of the challenges in producing SOI wafers and devices based on such structures with BS layers beneath the oxide, the present inventor has recognized a need to provide for bonding an oxide layer to a predominantly silicon surface with low-defectivity and high reproducibility and reliability while accommodating a buried stressor layer such as silicon germanium. In one embodiment, the present invention provides a method for forming a BS layer, such as silicon germanium, with a substantially pure silicon “bonding layer” at its upper surface, to which a buried oxide layer is bonded. The silicon bonding layer (“BL”) provides a predominantly silicon surface that enables improved bonding of a buried oxide layer of an SOI wafer. The invention also includes, in some embodiments, a semiconductor structure (and/or a device made from or in such a structure) having a layer arrangement consisting of an SOI layer over a BOX over a BS layer such as silicon germanium with a silicon BL intervening between the BOX and the BS layers. The silicon BL may be exceedingly thin, as thin as a monolayer of silicon, but more generally one or two nm thick so the surface remains chemically and physically a substantially silicon surface at the time of bonding to the oxide layer after cleaning and wet and dry conditioning treatments have been applied.

The substantially pure silicon BL may be formed by epitaxial growth on top of the BS layer, with the BS layer itself having been grown epitaxially. The distinct BS and BL (e.g., silicon germanium and silicon, respectively) layers may be formed in a continuous process in the same epitaxial deposition tool. The BS layer is not necessarily of uniform composition with depth. For example, a silicon germanium BS layer may be graded, starting with a low composition of germanium at the interface with the underlying silicon handle wafer and increasing with distance from that interface up to a higher level of germanium composition in the range 10% to 100%. The grading may extend over tens of nanometers and need not necessarily be linear. In a preferred embodiment, the germanium in the silicon germanium BS layer is graded from a low concentration between 0% and 20% at its interface with the underlying silicon handle wafer to a high concentration in the range of 50% to 100% at its interface with the BL layer. The grading of the germanium concentration is applied across a silicon germanium layer thickness of between 20 nm and 200 nm and most preferably between 40 nm and 100 nm.

In another embodiment, the substantially pure BL may alternatively be formed by epitaxial growth at the top of a BS layer of graded composition, with the germanium fraction in the silicon germanium alloy being graded from a high value to zero, or close to zero, at the top surface (i.e., the interface with the BL layer). As an example, a silicon germanium layer may be formed with a starting composition of 40% germanium on a silicon wafer and the composition then graded down to negligible germanium at the top surface. The grading may extend over tens of nanometers and need not necessarily be linear.

In another example, a BS layer (e.g., silicon germanium) may be formed on a silicon handle wafer, starting with a low germanium fraction, grading up to a high fraction around 50% or more then grading back down to a negligible germanium faction at the top surface. The graded layers may have thicknesses in the range of tens of nanometers. The grading need not necessarily be linear.

After bonding, high temperature processes may be applied to the wafer, either as part of the SOI wafer production process or during the processing of semiconductor devices on the SOI wafers. The high temperature processes may cause germanium in a silicon germanium BS layer to diffuse, upwards and downwards (with these directions being oriented orthogonal, or approximately so, to the plane of the BS layer), with the upward diffusion of germanium transforming the silicon BL layer to silicon germanium. In such cases, a distinct silicon bonding layer may no longer be discernable in the finished device and the silicon germanium BS layer may be observed to extend all the way to the BOX layer, even though an intervening silicon bonding layer had existed at the time of bonding.

In other embodiments, the silicon BL intervening between the BOX and the BS layer remains at the end of the device manufacturing process. In such embodiments, it may be advantageous that the work function of the back gate is the work function of silicon, as is customary in SOI device design. That is, despite the presence of the BS layer, which may have a work function different than silicon, especially when doped p-type, the work function of the back gate will be the work function of the silicon BL, which may be doped n-type or p-type, as appropriate, in the course of a device manufacturing process.

Referring now to FIG. 18, a semiconductor structure 300 is shown. The structure includes, in sequence, a semiconductor substrate (e.g., Si, or a semiconductor alloy containing Si) 312, a buried stressor (BS) layer (e.g., a silicon germanium layer) 314, a thin bonding layer (BL) of silicon 316, a BOX layer 318, and an active semiconductor (e.g., Si, or a semiconductor alloy containing Si) layer 320. Semiconductor structure 300 may be comprise an entire wafer or just a portion thereof.

In one embodiment, semiconductor structure 300 is formed by first forming the BS layer 314 on the substrate 312. In one example, the BS layer is silicon germanium and the substrate is silicon or a semiconductor alloy containing silicon, and BS layer 314 is grown epitaxially on the substrate 312. Preferably, the BS layer is grown to a thickness less than a “critical thickness,” at which misfit dislocations are generated. The BL 316 may be very thin, for example as thin as a monolayer, but is more generally one or two nm thick so the surface remains chemically and physically suitable for bonding to the BOX layer after it has been cleaned and conditioned. BL 316 may be formed by epitaxial growth on top of BS layer 314, with BS layer 314 itself having been grown epitaxially as discussed above. The distinct BS and BL (e.g., in one embodiment silicon germanium and silicon, respectively) layers 314, 316, may be formed in a continuous process.

To complete the formation of the layered structure 300 shown in FIG. 18, a “wafer bonding” process may be employed. In this procedure, a silicon oxide layer 318, e.g., of thickness in the range 5 nm to 80 nm, is formed on a donor silicon wafer, while the in-plane, compressively strained BS layer 314, of thickness in the range 5 nm to 70 nm, is formed by an epitaxial growth process (such as chemical vapor deposition, “CVD”) on a separate handle wafer. In one embodiment, the BS layer 314 may be silicon germanium, with an alloy composition between 5% germanium and 100% germanium and a thickness less than the “critical thickness” at which plastic relaxation occurs with formation of extended defects such as dislocations. The BL layer (e.g., silicon) 316 is then grown epitaxially over the BS layer 314 on the handle wafer, and the oxide layer 318 of the donor wafer is subsequently bonded to the BS layer 316 of the handle wafer. Because the BS layer 316 is pure silicon, conventional bonding techniques for silicon oxide to silicon can be employed. A majority of the thickness of the silicon donor wafer is then removed by any combination of processes to leave a thin layer of silicon 320 (e.g., a thickness in the range 2 nm to 50 nm) remaining on the silicon oxide layer 318 and the silicon oxide layer 318 bonded to the silicon BL layer 316 above the silicon germanium BS layer 314. The range of processes available for thinning the silicon layer 320 include: wafer cleaving (after proton or hydrogen implantation); wafer polishing; chemical mechanical polishing (“CMP”); and cyclic oxidation and wet etching with a solution of hydrofluoric acid.

After bonding, high temperature processes may be applied to the wafer, either as part of the SOI wafer production process or during the processing of semiconductor devices on the SOI wafers. Those high temperature processes may cause germanium in the BS layer 314 to diffuse, upwards and downwards (with respect to the plane of BS layer 314), with the upward diffusion of germanium transforming the silicon layer 316 to silicon germanium. In such cases, a distinct silicon bonding layer 316 may no longer be discernable in the finished device and a silicon germanium BS layer 314 may be observed to extend all the way to the BOX layer 318, even though an intervening silicon bonding layer 316 had existed at the time of bonding. The presence of germanium at the bottom interface of the BOX layer 318 may cause electrically active defects to be present at that interface when fabrication of an integrated circuit is completed and those defects may inhibit electrical conduction at that interface. A higher concentration of germanium at the bottom interface of the BOX layer may cause a higher concentration of electrically active defects at that interface and consequently a greater inhibition of electrical conduction at that interface in the finished integrated circuit.

In other embodiments, the silicon layer 316 intervening between the BOX layer 318 and the BS layer 314 remains at the end of the device manufacturing process. In such embodiments it may be advantageous that the work function of the back gate is the work function of silicon. That is, despite the presence of the buried silicon germanium, which may have a work function different than silicon, the work function of the back gate will be the work function of the silicon bonding layer, which may be doped n-type in the course of device manufacturing process.

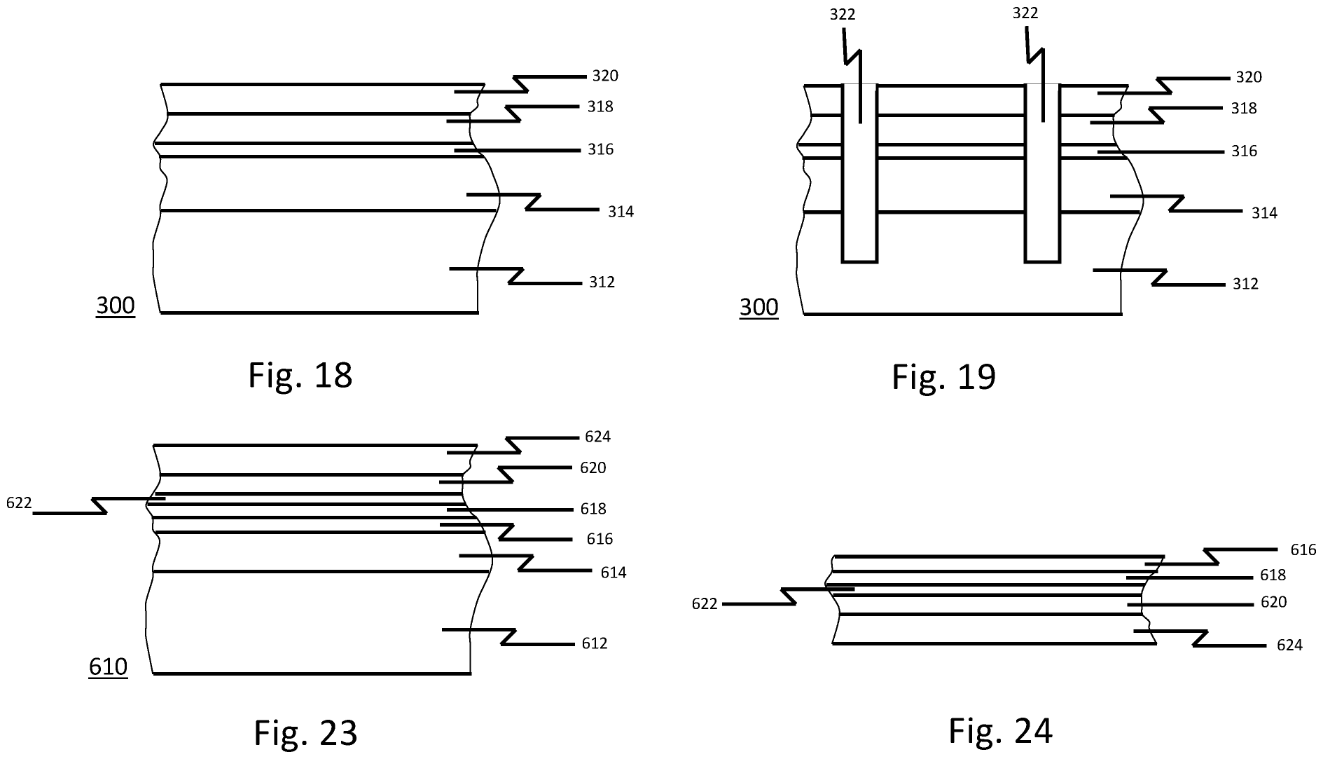

Referring now to FIG. 19, after formation of the layered structure from FIG. 18, a pattern is created in a resistive material on the surface of the silicon layer 320 by any known lithographic method, the pattern defining trenches to be etched. Subsequently, trenches 322 are etched to a depth sufficient to pass through the BL and BS layers and into the underlying silicon. The trench etching process may be a dry etch process (such as plasma etching or reactive ion etching) or a wet etch process (such as buffered HF) or a combination of dry and wet etching processes. The resistive material is removed after completion of the trench etching process. After trench etching, a brief thermal process may be applied and then the trenches may be filled with an insulating material such as silicon dioxide. The brief thermal process may have a duration of between 1 millisecond and 60 seconds and may reach a maximum temperature of between 600° C. and 1200° C. The thermal process may be rapid thermal annealing (RTA), flash lamp annealing, laser annealing or any other rapid heating process. At the end of the process, the buried oxide 318 may be deformed, specifically as a result of it being thinner at the trench sidewalls due to migration of some of the silicon oxide laterally beyond the boundary of the trench sidewall.

Active devices, such as transistors, may be fashioned in or from semiconductor structure 310, for example, where the channel of such devices is present in semiconductor layer 320.

The BS layer 314 is not necessarily of uniform composition with depth. For example, a silicon germanium BS layer may be graded, starting with a low composition of germanium at the interface with the underlying silicon substrate 312, and increasing with distance from that interface up to a higher level of germanium composition in the range 40% to 100%. The grading may extend over tens of nanometers and need not necessarily be linear. In a preferred embodiment, the germanium in the silicon germanium BS layer is graded from a low concentration between 0% and 20% at its interface with the underlying silicon handle wafer to a high concentration in the range of 40% to 100% at its interface with the BL layer. The grading of the germanium concentration is applied across a silicon germanium layer thickness of between 20 nm and 200 nm and most preferably between 40 nm and 100 nm.

The substantially pure BL 316 may alternatively be formed by epitaxial growth at the top of a BS layer 314 of graded composition, with the germanium fraction in the silicon germanium alloy being graded from a high value to zero, or close to zero, at the top surface (i.e., the interface with the BL layer). As an example, a silicon germanium layer may be formed with a starting composition of 40% germanium on silicon substrate 312, and the composition then graded down to negligible germanium at the top surface interface with BL 316. The grading may extend over tens of nanometers and need not necessarily be linear.

In another example, the BS layer 314 may be formed on silicon substrate 312, starting with a low germanium fraction, grading up to a high fraction around 50% or more, then grading back down to a negligible germanium faction at the top interface with BL 316. The graded layers may have thicknesses in the range of tens of nanometers. The grading need not necessarily be linear.

The invention is not limited to use of a silicon germanium BS layer or a silicon upper layer. The buried compressive stressor layer may be a silicon nitride layer and upper semiconductor layer 320 may be a semiconductor other than silicon such as: germanium; a silicon germanium alloy; germanium tin; silicon carbon or some other group IV semiconductor; a III-V compound semiconductor or a II-VI compound semiconductor; graphene or a transition metal dichalcogenide semiconductor.

Silicon Germanium Back Gate:

Above, mention was made of a “back gate.” It is common for a semiconductor underlying and adjoining a buried oxide in a fully depleted silicon-on-insulator (“FDSOI”) field effect transistor (“FET”) to be doped and electrically contacted and used as a fourth terminal—a so-called “back gate.” The back gate is especially effective when the buried oxide is ultra-thin (i.e., less than 50 nm and preferable less than 30 nm). A bias voltage may be applied to the back gate to modulate the threshold voltage of the FET.

The electrical potential of the back gate in the absence of an applied voltage bias is determined by the Fermi level in the back gate at the location where the back gate material forms an interface with the BOX. If the back gate material is silicon and it is doped n-type to a concentration approximately 2×10¹⁹ donors/cm³, the Fermi level is at or near the silicon conduction band. The location of the Fermi level relative to the conduction band in n-type silicon is given quite accurately by the Fermi-Dirac equation as a function of the n-type doping concentration. Similarly, if the back gate material is silicon and it is doped p-type to a concentration around 2×10¹⁹ acceptors/cm³, the Fermi level is at or near the silicon valence band. The location of the Fermi level relative to the valence band in p-type silicon is given quite accurately by the Fermi-Dirac equation as a function of the p-type doping concentration. The doping concentration has a direct influence over the energy of the Fermi level, which lies below the valence band for p-type doping concentrations in excess of about 2×10¹⁹ acceptors/cm³ and above the valence band for p-type doping concentrations less than about 2×10¹⁹ acceptors/cm³.

In embodiments of the present invention, the back gate material is silicon germanium alloy rather than silicon. The p-type dopant (acceptor) concentration in the silicon germanium determines the Fermi level relative to the valence band as it does in p-type silicon. But the present invention provides an additional control over the Fermi level in the back gate through the alloy composition of the silicon germanium. As the germanium fraction in the silicon germanium alloy is increased, the valence band energy is raised to be closer to the conduction band energy (that is, the band gap is reduced). Thus, a silicon germanium back gate has an electrical potential that is a function of both the doping at the interface with the silicon BL layer (or the BOX if the silicon BL layer is made indistinguishable as a result of various processing steps) and the germanium fraction at the interface with the silicon BL layer (or the BOX).

In one embodiment of the invention, a p-type silicon germanium back gate has approximately constant composition with depth, the Fermi level of the back gate being determined by the alloy composition and p-type doping in the silicon germanium at its interface with the silicon BL layer (or the BOX). In another embodiment, the silicon germanium back gate has composition that varies with depth, the Fermi level of the back gate being determined by the alloy composition and p-type doping in the silicon germanium at its interface with the BOX. By having a varying composition, it is possible to separately optimize (a) the Fermi level of the back gate at the interface with the BOX, which has electrical consequences for the electrical operation of the transistor, and (b) the stress profile in the buried silicon germanium layer which has consequences for the level of tensile strain induced in the semiconductor layer 320, and therefore the electrical performance of the transistor through modification of the electron mobility and/or effective mass in the semiconductor layer 320.

Hard Mask/STI Fill Solutions—to Unconstrain Edge Relaxation:

It was noted in U.S. Pat. Nos. 8,395,213 and 9,406,798 that in conventional processes for etching isolation trenches (e.g., a shallow trench isolation or “STI” process), a silicon nitride hard mask is typically used and that such a hard mask may inhibit edge relaxation of the buried stressor layer. If edge relaxation is inhibited, the amount of strain induced in the upper semiconductor layer may be significantly lower than expected.

The present applicant has determined by experiment that a silicon nitride hard mask can be very efficient in suppressing edge relaxation to the extent that n-channel FETs exhibited no detectable increase in drive current when switched on (gate and drain potentials both high) whether or not a buried stressor layer was incorporated under a semiconductor channel layer. Strain characterization by nanobeam diffraction of an example nFET with a buried silicon germanium stressor layer in a transmission electron microscope confirmed that negligible strain was induced in the silicon channel layer overlying a silicon germanium buried stressor, and moreover, that the silicon germanium buried stressor layer was not relaxed to a significant degree.

The constraining effect of the silicon nitride layer presents a significant challenge to the application of the buried stressor approach wherever it is desired to induce in-plane tensile strain in a semiconductor layer, such as in nFETs. The constraining effect of the hard mask could, in principle, be overcome by etching away the silicon nitride after etching the trenches. However, in a typical STI process the trenches are filled with insulating silicon oxide before the hard mask is removed and the STI fill continues to inhibit edge relaxation even after the silicon nitride hard mask is removed. A need arises therefore for STI processing methods that permit edge relaxation to occur in STI structures with buried stressors including those formed in SOI wafers with the buried stressor within or beneath the buried insulator (buried oxide) layer.

In one embodiment, the present invention provides a process that mitigates the constraining effect of a silicon nitride hard mask by either of two categories of methods: In a first approach. The silicon nitride hard mask is softened to make it more compliant either before or after etching of the trenches and before filling the trenches with silicon oxide. In a second approach, the STI trench fill material is softened to make it more compliant after removal of the silicon nitride hard mask.

In regard to the first approach (softening the hard mask), it is known that ion implantation into a thin layer of silicon nitride may (i) soften the silicon nitride, and/or (ii) cause the silicon nitride layer to be under compressive stress. Either or both of (i) and (ii) is beneficial to the tensile straining of a layer of semiconductor with a silicon nitride hard mask on top and a compressively stressed buried stressor layer beneath, with trenches etched as described above to cause elastic edge relaxation. Accordingly, both approaches are contemplated by the present inventor.

In one embodiment of this invention, a silicon nitride hard mask is softened such that the mechanical impedance of elastic edge relaxation by the silicon nitride is reduced and the top semiconductor layer is put under tensile strain before the STI trenches are filled and planarized and the hard mask subsequently removed. In another embodiment of this invention, the silicon nitride hard mask is put under compressive stress in the plane of the wafer by an ion implantation such that the compressive nitride exerts a force additional to that from the buried stressor layer, causing the top semiconductor layer to be put under tensile strain before the STI trenches are filled and planarized and the hard mask subsequently removed.

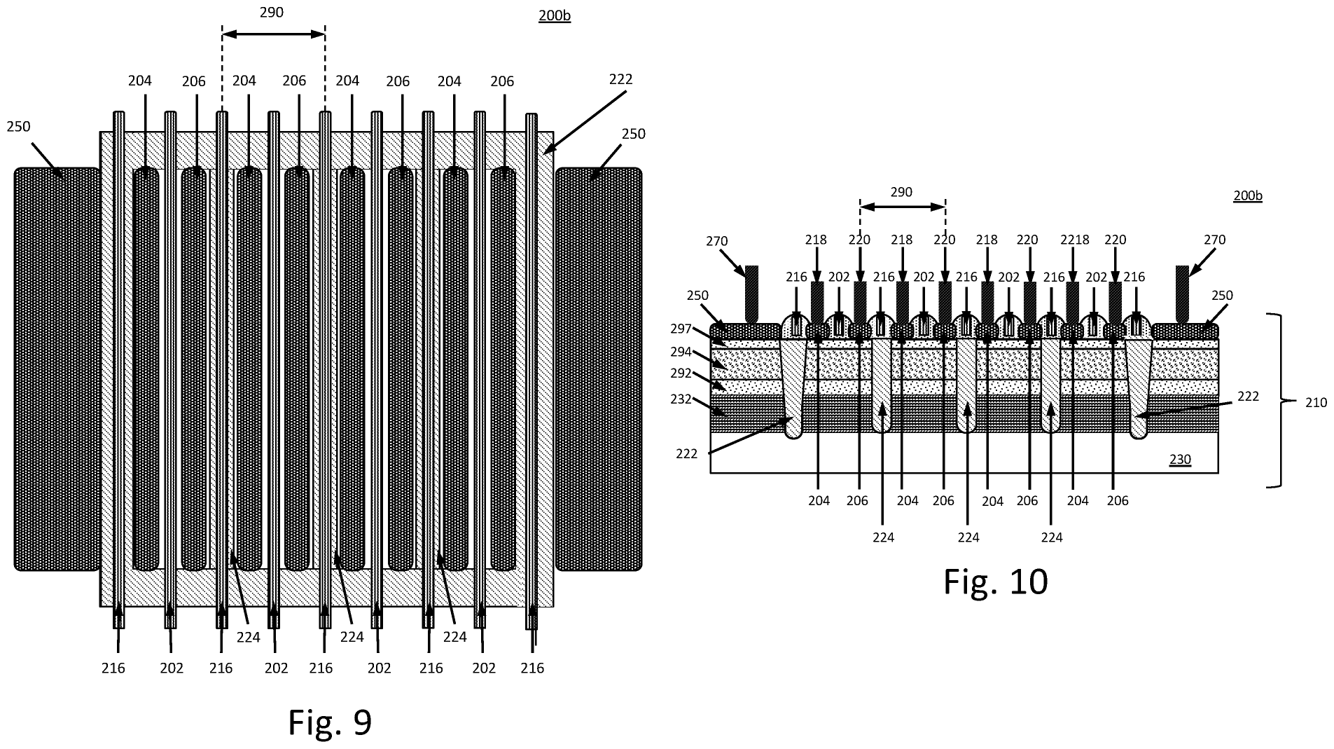

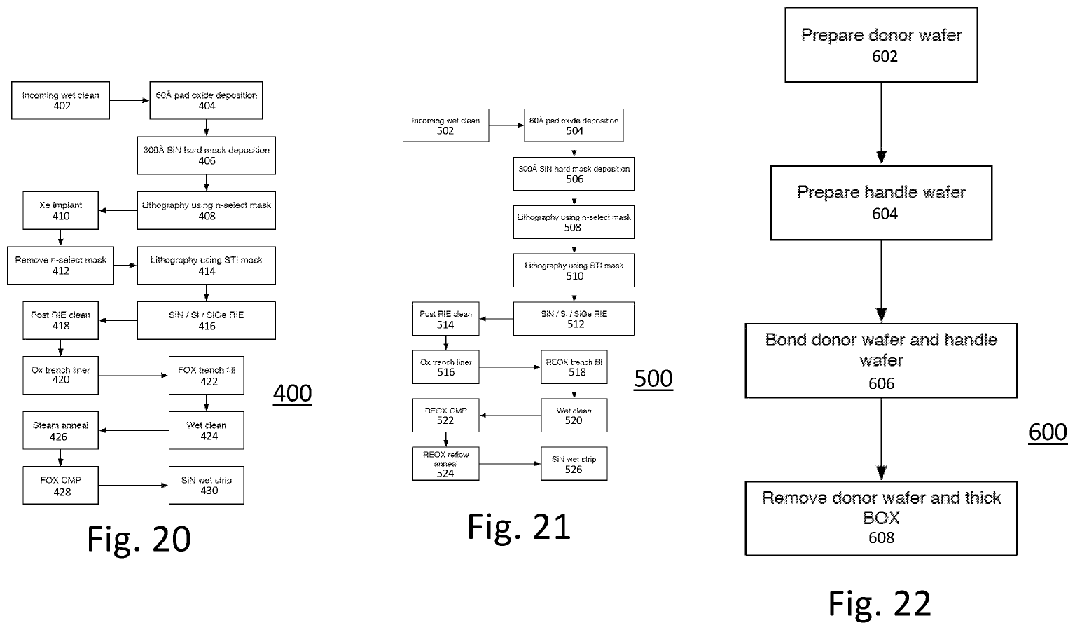

An example of a process 400 for softening a silicon nitride hard mask in accordance with the present invention is illustrated in FIG. 20. At 402, a semiconductor wafer 300 having the layer structure shown in FIG. 9 is subject to a wet clean using a solvent, followed by a deionized water rinse. Typically, a two solvent cleaning process will be used to remove oils and organic residues, as well as residues from the first solvent (typically acetone). In one embodiment, the silicon wafer is placed in a warm (e.g., 55° C.) acetone bath for approximately ten minutes, and then transferred to a methanol bath for approximately 2-5 min. The wafer is removed from the methanol and rinsed with deionized water. Optionally, the wafer may then be blown dry with nitrogen. Following the solvent clean, the wafer may be cleaned of organic residue using a conventional RCA clean involving a mixture of ammonium hydroxide and hydrogen peroxide. The RCA clean leaves a native oxide on the wafer, which is removed using a conventional HF dip.

Next at 404, a 60 A pad oxide is grown or deposited on the wafer, followed by deposition of a SiN hard mask at 406. The hard mask may be deposited to a thickness of approximately 300 Å. The mask is subsequently patterned using a resist 408 in an n-select manner, and an Xe implant at, for example, 40 Key and 100 KeV is carried out 410.

Following the ion implant, the n-select mask is removed 412, and an STI resist mask applied 414. The SiN hard mask, Si layer 320, BOX layer 318, BL layer 316, and SiGe BS layer 314 are then etched 416 to form trenches 322. The etch may be a reactive ion etch and may extend partially into the substrate 312. Following the etch, a post-RIE cleaning process is performed 418.

The wafer now has a structure similar to that illustrated in FIG. 19, with trenches 322 located at regions dictated by the STI mask. The trenches 322 are provided with an oxide liner 420, for example through deposition of TEOS or thermal growth, and thereafter a field oxide (e.g., silicon oxide) is deposited (e.g., at 5 kA) to fill the trenches 422.

One the trenches have been filled with the deposited oxide, the wafer is again subjected to a wet clean 424, followed by a steam anneal at approximately 500° C. 426. The remaining FOX is removed using a chemical mechanical polish process 428, and the remaining silicon nitride hard mask is removed using a wet strip 430.

In the second approach for mitigating the constraining effect of a silicon nitride hard mask, the STI trench fill material is softened to make it more compliant after removal of the silicon nitride hard mask. It is known that some silicon oxide formulations that may be applied as STI trench fill material may be softened and/or reflowed during a brief, high temperature annealing cycle after the trenches have been filled. After removal of the silicon nitride hard mask and during a period of time that the STI fill material is softened and/or reflowed by heating to a sufficiently high temperature, elastic edge relaxation is able to occur quite unimpeded and tensile strain is induced in a semiconductor layer overlying a buried stressor layer.

Accordingly, in an embodiment of this invention, the STI trenches are filled with an insulating material that may be softened and/or reflowed during a brief, high temperature annealing cycle. The insulating material is planarized and the hard mask subsequently removed. After removal of the silicon nitride hard mask, the assembly is heated to a temperature sufficient to cause softening and/or reflow of the STI fill material, thus allowing elastic edge relaxation of the buried stressor to occur and thus causing the top semiconductor layer to be put under in-plane tensile strain.

An example of a process 500 for softening STI trench fill material in accordance with the present invention is illustrated in FIG. 21. As with the process for softening the hard mask, at 502 a semiconductor wafer 300 having the layer structure shown in FIG. 18 is subject to the wet clean procedure described above. Next at 504, a 60 A pad oxide is grown or deposited on the wafer, followed by deposition of a SiN hard mask at 506. The hard mask may be deposited to a thickness of approximately 300 Å. The mask is subsequently patterned using a resist 508 in an n-select manner, and then patterned using an STI resist mask 510. The Si layer 320, BOX layer 318, BL layer 316, and SiGe BS layer 314 are then etched 512 to form trenches 322. The etch may be a reactive ion etch and may extend partially into the substrate 312. Following the etch, a post-RIE cleaning process is performed 514.

The wafer now has a structure similar to that illustrated in FIG. 19, with trenches 322 located at regions determined by the STI mask. The trenches 322 are provided with an oxide liner 516, for example through deposition of TEOS or thermal growth, and thereafter the trenches are filled with an oxide 518. This time, the oxide is a reflowable silicon oxide (REOX).

One the trenches have been filled with the REOX, the wafer is again subjected to a wet clean 520, followed by removal of the REOX using a chemical mechanical polish process 522. The REOX is then allowed to reflow during an anneal 524, and the remaining silicon nitride hard mask is removed using a wet strip 526.

Avoiding Tensile Strain in PFETs by not Relaxing Hard Mask on PFETs:

It is generally understood that longitudinal tensile strain (i.e., uniaxial tensile strain directed along the same axis as electron flow) is beneficial to the performance of n-channel FETs due to the mobility and velocity of electrons being improved by the uniaxial tensile strain. In an embodiment of the invention, tensile strain is induced in nFETs by edge relaxation of buried stressor layer (e.g., a silicon germanium layer). On the other hand, longitudinal tensile strain adversely affects the performance of p-channel FETs due to the mobility and velocity of holes being degraded by the tensile strain. Put another way, longitudinal in-plane uniaxial tensile strain parallel to the direction of carrier flow is generally beneficial in nFETs but generally undesirable in pFETs. Yet nFETs are sometimes fabricated alongside pFETs in a common semiconductor layer. The need arises therefore to obtain longitudinal uniaxial tensile strain parallel to the direction of carrier flow only in nFETs while avoiding longitudinal in-plane tensile strain parallel to the direction of carrier flow in pFETs.

Accordingly, in an embodiment of the invention longitudinal tensile strain in pFETs is avoided by using silicon nitride hard mask to inhibit edge relaxation in pFETs. At the same time, longitudinal tensile strain in permitted nFETs (typically manufactured in the same semiconductor layer as the pFETs) by selectively relaxing silicon nitride hard mask over the nFETs only (e.g., by ion implantation as discussed above). In one example, a silicon nitride hard mask is used to resist most or all of the tensile straining of an underlying semiconductor layer (e.g., Si layer 320 in the structure shown in FIG. 9), for example due to edge relaxation of a buried stressor, wherever a p-channel transistor is formed in the semiconductor layer.

In one embodiment, a silicon nitride hard mask layer is formed over a semiconductor layer which itself is disposed over a compressive buried stressor layer. A patterned ion implantation mask is formed over the silicon nitride hard mask layer such that there are windows in the implantation mask corresponding to the intended locations of n-channel FETs (nFETs). Then, the silicon nitride hard mask layer is implanted with a species of ions of appropriate energy and dose through the windows in the implantation mask to soften the silicon nitride and/or cause the silicon nitride to be under in-plane compressive stress only wherever it is exposed to the ions. The implanted ions do not enter the silicon nitride hard mask layer except where it is exposed by a window in the implantation mask. After the ion implantation, the implantation mask is removed and an STI mask pattern is formed over the silicon nitride hard mask layer, the STI mask pattern defining active regions corresponding to both nFETs and pFETs. Then, isolation trenches are etched through the silicon nitride hard mask layer, the semiconductor layer and the compressive buried stressor layer (and any intervening oxide and BL layers, if present) in a pattern as defined by the STI mask pattern. By this method, edge relaxation is only effective in the nFET regions due to the softening of the silicon nitride mask and/or compressive stress in the silicon nitride hard mask that resulted from the ion implantation step.

Avoiding Tensile Strain in PFETs by not Etching Deep STI Trenches to Isolate PFETs:

In an embodiment of the invention, tensile strain is induced in nFETs by edge relaxation of buried stressor layer (e.g., a silicon germanium layer). On the other hand, longitudinal tensile strain adversely affects the performance of p-channel FETs due to the mobility and velocity of holes being degraded by the tensile strain. Put another way, longitudinal in-plane uniaxial tensile strain parallel to the direction of carrier flow is generally beneficial in nFETs but generally undesirable in pFETs. Yet nFETs are sometimes fabricated alongside pFETs in a common semiconductor layer. The need arises therefore to obtain longitudinal uniaxial tensile strain parallel to the direction of carrier flow only in nFETs while avoiding longitudinal in-plane tensile strain parallel to the direction of carrier flow in pFETs. In the invention, longitudinal tensile strain is avoided in PFETs by etching the isolation trenches at the ends of the PFET active regions to a depth that does not extend to the bottom of the BS layer and more preferably to a depth that does not extend to the top of the BS layer. In FDSOI embodiments, the isolation trenches for PFETs may penetrate no deeper than the BOX layer. Or if the trenches do penetrate through the BOX layer, they do not penetrate deeper than the bottom interface of the BS layer that is under the BOX layer.

Low Temperature Ultra-Thin SOI Method—Compatible with Silicon Germanium Stressor:

A further challenge in the production of SOI wafers with BS layers and of semiconductor devices based on such structures arises if the BS layer is a material, for example silicon germanium alloy, that cannot withstand a large thermal budget either because of degradation of the BS layer or diffusion of the BS layer or reaction of the BS layer with the BOX. Such a challenge arises specifically in the production of ultra-thin SOI wafers when the SOI layer is thinned by techniques that include high temperature oxidation steps. In the currently prevalent method of SOI wafer fabrication, the SOI layer is split off from a handle wafer and is subsequently thinned by thermal oxidation of the SOI layer and removal of the silicon oxide by hydrofluoric acid. Target thickness for the SOI layer is currently approximately 13 nm with uniformity of plus/minus 0.2 nm.

In some embodiments of the present invention, an ultra-thin and uniform SOI layer (such as Si layer 320) is formed over a BOX (such as layer 318) without recourse to thermal oxidation or the need for chemical mechanical polishing. The method(s) enable integration of a buried stressor layer underneath the BOX that could otherwise be degraded by high temperature thermal oxidation treatments of the composite SOI wafer. In such embodiments of the invention, a semiconductor layer of desired composition and thickness that will become the SOI layer of the finished wafer is prepared so as to provide a sacrificial release layer between the SOI layer and the donor wafer that allows separation of the SOI layer by a low temperature etch process. The release layer must have a different chemical composition than the SOI layer so that it may be etched selectively after bonding the SOI layer to the handle wafer, leaving the SOI layer in place on the BOX and releasing the donor wafer. An example release layer is epitaxial silicon germanium. Chemical etches are known that can remove silicon germanium, while leaving silicon relatively untouched. Another release layer that can be used in accordance with the invention is silicon oxide. Wet chemical etches, such as buffered hydrofluoric acid, are known that can remove silicon oxide very selectively while leaving silicon almost completely intact.

Embodiments of the invention include an optional step of patterning and etching holes through the donor wafer across the lateral extent of the donor wafer to allow the release etchant to access the release layer at many points or lines across the lateral extent of the release layer.

With reference to FIG. 22, one example of a process 600 to provide an SOI wafer consisting of a thin SOI layer over a thin BOX layer over a buried stressor layer on a silicon handle wafer is as follows: At 602, the donor wafer is prepared. This entails forming an ultra-thin SOI wafer with an ultra-thin layer of a semiconductor of desired composition and thickness and a sacrificial BOX layer that is not ultra-thin between the ultra-thin layer of semiconductor and the donor wafer. Any conventional technique for forming and thinning of the SOI layer to a desired, uniform thickness may be used. There is no thermal limitation on this procedure, as it is undertaken in the absence of a thermally-sensitive buried stressor layer. Next, a thin BOX layer is formed on the surface of the SOI layer, for example by oxidation of the surface of the ultra-thin SOI layer. Finally, hydrogen ions are implanted to a depth greater than the bottom interface of the sacrificial BOX layer.

Next, at 604, the handle wafer is prepared. Note, this step may be done completely independently of step 602. The handle wafer will include a buried stressor layer. In one embodiment, the buried stressor layer is formed on a silicon wafer, and may be compressively strained epitaxial silicon germanium, optionally terminated by a surface silicon bonding layer as discussed above. The compressively strained epitaxial silicon germanium may have a graded composition of the silicon germanium alloy with a low concentration of germanium at the bottom interface with the underlying silicon wafer and a high concentration in the range 40% to 100% at the top of the silicon germanium layer. The buried stressor layer may, in another embodiment, alternatively be compressively or tensile strained silicon nitride. In still other embodiments, the buried stressor layer may be compressively or tensile strained metallic material. Once formed, the surface of the handle wafer is cleaned and conditioned by a conventional wet or dry technique.

At 606, the donor and handle wafers are bonded. Any conventional bonding technique may be employed such that the thin BOX layer on the surface of the donor wafer contacts the buried stressor layer on the surface of the handle wafer, where the buried stressor layer may optionally be terminated by a thin silicon layer as discussed above. The result is a composite structure 610, illustrated in FIG. 23, consisting of, in sequence: bulk donor wafer 612, sacrificial thick BOX layer 614, thin SOI layer 616, thin BOX layer 618, BS layer 620 (with optional BL layer 622 between the BS layer and the thin BOX layer), and bulk handle wafer 624.

At 608, the donor wafer 612 and sacrificial thick BOX layer 614 are removed to leave a thin SOI layer 616 on thin BOX layer 618 on BS layer 620 (with optional BL layer 622 between the BS layer and the thin BOX layer) on bulk handle wafer 624, as shown in FIG. 24. A major portion of the bulk donor wafer may be split off by any conventional splitting or exfoliation technique, such as the SmartCut process, leaving a minor portion of the bulk donor wafer 612 attached to the thick BOX layer 614. Thereafter, the remaining portion of the bulk donor wafer may be removed by a conventional selective dry or wet chemical etch, leaving the thick BOX layer 614 exposed. The thick BOX layer 614 may be removed using a conventional selective dry or wet chemical etch, e.g. a buffered HF wet etch, leaving the ultra-thin SOI layer 616 exposed.

Thus, strained semiconductor MOSFET devices, and in particular embodiments of strained multi-finger RF MOSFET devices, including strained FD-SOI and PD-SOI RF MOSFETs, formed using substrates having a buried stressor layer to provide said devices with strained silicon active regions and methods of making such devices have been described. At least each of the following embodiments are contemplated:

Embodiment 1: An RF MOSFET, comprising respective pluralities of gate fingers, source fingers, and drain fingers formed on a semiconductor structure, the gate fingers being spaced apart from each other along a first direction, extending in a second, orthogonal direction, and electrically connected to one another through a gate mandrel that is electrically connected to a gate contact, the source fingers being spaced apart from each other along the first direction, extending in the second direction, and electrically connected to one another through a source mandrel that is electrically connected to respective source contacts, and the drain fingers being spaced apart from each other along the first direction, extending in the second direction, and electrically connected to one another through a drain mandrel that is electrically connected to respective drain contacts, the respective source, gate, and drain fingers further being interdigitated so that each gate finger extends in the first direction between a pair of adjacent source and drain fingers, the RF MOSFET electrically organized as a plurality of unit cell transistors electrically connected with one another and adjacent unit cell transistors of the RF MOSFET being separated from one another by a dummy gate and trench that extends into the semiconductor structure.

Embodiment 2: The RF MOSFET of embodiment 1, wherein the semiconductor structure is a bulk semiconductor substrate with a buried stressor layer disposed over the semiconductor substrate and a semiconductor layer disposed over the buried stressor layer.

Embodiment 3: The RF MOSFET of embodiment 1, wherein the semiconductor structure is a PD-SOI wafer including a semiconductor substrate, a BOX layer disposed over the semiconductor substrate, a semiconductor layer disposed over the BOX layer, a buried stressor layer disposed over the semiconductor layer, and a partially depleted semiconductor layer disposed over the buried stressor layer.

Embodiment 4: The RF MOSFET of embodiment 1, wherein the semiconductor structure is an FD-SOI wafer including a semiconductor substrate, a buried stressor layer disposed over the semiconductor substrate, a BOX layer disposed over buried stressor layer, and a fully depleted semiconductor layer disposed over the BOX layer.

Embodiment 5: The RF MOSFET of any one of embodiments 1-4, wherein the dummy gates are not electrically connected to the gate mandrel.

Embodiment 6: The RF MOSFET of any one of embodiments 1-5, wherein the gate, source and drain fingers are each made of a conductive material.

Embodiment 7: The RF MOSFET of any one of embodiments 1-6, wherein each unit cell transistor includes one of the gate fingers, one of the source fingers, and one of the drain fingers, the included source and drain fingers being on opposed sides of the included gate finger, and a portion of the semiconductor structure that underlies the included gate, source and drain fingers.

Embodiment 8: The RF MOSFET of any one of embodiments 1-7, wherein the source fingers and drain fingers comprise elevated epitaxial silicon source/drain regions and a source/drain of each unit cell transistor is located inside the included portion of the semiconductor structure that underlies an adjacent a channel region below a respective included gate finger.

Embodiment 9: The RF MOSFET of any one of embodiments 1-8, wherein the buried stressor layer comprises SiGe.

Embodiment 10: The RF MOSFET of embodiment 2, wherein the trenches extend through the semiconductor layer and the buried stressor layer and into the underlying substrate.

Embodiment 11: The RF MOSFET of embodiment 3, wherein the trenches extend through the partially depleted semiconductor layer, the buried stressor layer, the semiconductor layer, and into the BOX layer.

Embodiment 12: The RF MOSFET of embodiment 3, wherein the trenches extend through the partially depleted semiconductor layer, the buried stressor layer, the semiconductor layer, the BOX layer and partially into the substrate.

Embodiment 13: The RF MOSFET of embodiment 4, wherein the trenches extend through the fully depleted semiconductor layer, the BOX layer, the buried stressor layer, and into the substrate.

In some of the above-described embodiments, certain process sequences have been specified. However, in other embodiments, the order of steps in these sequences may be altered without departing from the present invention. For example, in some instances of the invention, trenches may be etched before a nitride hard mask is softened. Also, lithographic and etch processes to define and create active widths and active lengths may, in general, be performed in either order.

What is claimed is:

1. An RF MOSFET, comprising respective pluralities of gate fingers, source fingers, and drain fingers formed on a semiconductor structure, the gate fingers being spaced apart from each other along a first direction, extending in a second, orthogonal direction, and electrically connected to one another through a gate mandrel that is electrically connected to a gate contact, the source fingers being spaced apart from each other along the first direction, extending in the second direction, and electrically connected to one another through a source mandrel that is electrically connected to respective source contacts, and the drain fingers being spaced apart from each other along the first direction, extending in the second direction, and electrically connected to one another through a drain mandrel that is electrically connected to respective drain contacts, the respective source, gate, and drain fingers further being interdigitated so that each gate finger extends in the first direction between a pair of adjacent source and drain fingers, the RF MOSFET electrically organized as a plurality of unit cell transistors electrically connected with one another and adjacent unit cell transistors of the RF MOSFET being separated from one another by a dummy gate and trench that extends into the semiconductor structure.

2. The RF MOSFET of claim 1, wherein the semiconductor structure is a bulk semiconductor substrate with a buried stressor layer disposed over the semiconductor substrate and a semiconductor layer disposed over the buried stressor layer.

3. The RF MOSFET of claim 1, wherein the semiconductor structure is a PD-SOI wafer including a semiconductor substrate, a BOX layer disposed over the semiconductor substrate, a semiconductor layer disposed over the BOX layer, a buried stressor layer disposed over the semiconductor layer, and a partially depleted semiconductor layer disposed over the buried stressor layer.

4. The RF MOSFET of claim 1, wherein the semiconductor structure is an FD-SOI wafer including a semiconductor substrate, a buried stressor layer disposed over the semiconductor substrate, a BOX layer disposed over buried stressor layer, and a fully depleted semiconductor layer disposed over the BOX layer.

5. The RF MOSFET of claim 1, wherein the dummy gates are not electrically connected to the gate mandrel.

6. The RF MOSFET of claim 1, wherein the gate, source and drain fingers are each made of a conductive material.

7. The RF MOSFET of claim 1, wherein each unit cell transistor includes one of the gate fingers, one of the source fingers, and one of the drain fingers, the included source and drain fingers being on opposed sides of the included gate finger, and a portion of the semiconductor structure that underlies the included gate, source and drain fingers.

8. The RF MOSFET of claim 1, wherein the source fingers and drain fingers comprise elevated epitaxial silicon source/drain regions and a source/drain of each unit cell transistor is located inside the included portion of the semiconductor structure that underlies an adjacent a channel region below a respective included gate finger.

9. The RF MOSFET of claim 1, wherein the buried stressor layer comprises SiGe.

10. The RF MOSFET of claim 2, wherein the trenches extend through the semiconductor layer and the buried stressor layer and into the underlying substrate.

11. The RF MOSFET of claim 3, wherein the trenches extend through the partially depleted semiconductor layer, the buried stressor layer, the semiconductor layer, and into the BOX layer.

12. The RF MOSFET of claim 3, wherein the trenches extend through the partially depleted semiconductor layer, the buried stressor layer, the semiconductor layer, the BOX layer and partially into the substrate.

13. The RF MOSFET of claim 4, wherein the trenches extend through the fully depleted semiconductor layer, the BOX layer, the buried stressor layer, and into the substrate.
